(19) United States
(12) Patent Application Publication
(10) Pub. No.: US 2014/0232946 A1
(43) Pub. Date: Aug. 21, 2014

(54) DISPLAY APPARATUS AND TELEVISION RECEIVING APPARATUS

(71) Applicants: Yuhsuke Ebata, Osaka-shi (JP); Shuta Watanabe, Osaka-shi (JP); Katsushi Maeta, Osaka-shi (JP)

(72) Inventors: Yuhsuke Ebata, Osaka-shi (JP); Shuta Watanabe, Osaka-shi (JP); Katsushi Maeta, Osaka-shi (JP)

(73) Assignee: SHARP KABUSHIKI KAISHA, Osaka-shi, Osaka (JP)

(21) Appl. No.: 14/343,999

(22) PCT Filed: May 22, 2012
(86) PCT No.: PCT/JP2012/063010

§ 371 Date: Mar. 10, 2014

(30) Foreign Application Priority Data
Sep. 27, 2011 (JP) 2011-211555
Apr. 23, 2012 (JP) 2012-097963

(51) Int. Cl. H05K 5/02; H04N 5/64

(52) U.S. Cl. CPC H05K 5/02; H04N 5/64
USPC 348/836; 361/679.01

(57) ABSTRACT

Provided are a display apparatus and a television receiving apparatus with which safety may be assured while a casing is segmented. A display apparatus comprises: a display unit having a display screen in the front side thereof; a front cabinet which encompasses the peripheral edge part of the display unit; and a back cabinet which covers the rear side of the display unit. The back cabinet is formed from a back cabinet main body (41) in which an aperture (41a) is disposed, and a cover which is attached to the back cabinet main body (41) to close off the aperture (41a). The cover is configured from a material which differs from the material which configures the back cabinet main body (41).

### CROSS-REFERENCE TO RELATED APPLICATIONS

This application is the national phase under 35 U.S.C. §371 of PCT International Application No. PCT/JP2012/063010 which has an International filing date of May 22, 2012 and designated the United States of America.

### FIELD

The present application relates to a display apparatus and a television receiving apparatus such as a liquid crystal television, a plasma television or the like.

### BACKGROUND

A thin type display apparatus such as a thin type television, or the like has a casing including a front cabinet and a back cabinet, which cover a display unit. The back cabinet may be divided into a plurality of members for improving transportability, facilitating assembly or the like. (For example, see Japanese Patent Laid-open Publication No. 2009-171520 and Japanese Patent Laid-open Publication No. 2008-216347).

By the way, as the size of the thin type display apparatus becomes larger, it is necessary for a larger molding machine to mold the casing with rapidity. If it fails to introduce a new large molding machine into a system of producing the thin type display apparatus in time, the casing is divided into a plurality of members and each of the divided casing members is molded by an existing molding machine.

### SUMMARY

Meanwhile, in order to protect human life and properties from fire and other safety accidents, safety standards for fire protection and, mechanical and electrical protection relating to products and equipment have been defined. Therefore, even if the casing of the display apparatus is divided into a plurality of members, it is necessary to clear the safety standards such as those for fire protection and the like.

In consideration of the above-mentioned circumstances, it is an object of the present invention to provide a display apparatus and a television receiving apparatus capable of ensuring safety while dividing a casing thereof.

A display apparatus according to the present application including: a display unit having a display surface on a front side of the display unit; a front cabinet enclosing a peripheral edge part of the display unit; and a back cabinet covering a back side of the display unit, wherein the back cabinet includes a back cabinet body provided with an opening part and a cover body which is attached to the back cabinet body so as to close the opening part, and the cover body is made of a material different from the material constituting the back cabinet body.

The display apparatus according to the present application includes a display unit, a front cabinet and a back cabinet. The display unit has a display surface on the front side of the display apparatus. The front cabinet encloses the peripheral edge part of the display unit. The back cabinet covers the back side of the display unit. The back cabinet includes a back cabinet body and a cover body. The back cabinet body is provided with an opening part. The cover body is attached to the back cabinet body so as to close the opening part of the back cabinet body. The back cabinet body and the cover body are made of a different material each other.

If the back cabinet body and the cover body are made of the same material, costs may be increased. When any one of the back cabinet body and the cover body is made of a material having a low grade safety standard, the costs may be reduced. On the other hand, when the other one of the back cabinet body and the cover body is made of a material having a high grade safety standard, safety may be ensured.

In the display apparatus according to the present application, the cover body may be made of a material having a lower flame retardancy than the back cabinet body.

In the display apparatus according to the present application, the cover body and the back cabinet body are respectively made of resin materials having different flame retardancy.

According to the display apparatus of the present application, the cover body is made of a material having a lower flame retardancy than the back cabinet body. In a case that the opening part is located in a region of the back cabinet with a low risk of fire, when the cover body is made of a material having a lower flame retardancy than the back cabinet body, costs may be reduced. On the other hand, when the back cabinet body is made of a material having a high flame retardancy, safety in terms of fire protection may be ensured.

In the display apparatus according to the present application, may further include a circuit board fixed between the display unit and the back cabinet, wherein the opening part may be provided in a region not facing the circuit board in the back cabinet body.

According to the display apparatus of the present application, the circuit board is fixed between the display unit and the back cabinet. The opening part of the back cabinet body is provided in the region not facing the circuit board.

The circuit board is essentially a heating element that may reach a high temperature, if high voltage current is applied thereto. The cover body is a member which covers the opening part provided in the region not facing the circuit board. Therefore, even when the cover body is formed of a material having a low flame retardancy, there is no particular problem in terms of fire protection.

In the display apparatus according to the present application, the opening part may be provided in a region facing the display unit in the back cabinet body, and the back cabinet body may include an inner cylinder and an outer cylinder enclosing the inner cylinder, which are formed on a front surface of a periphery of the opening part.

According to the display apparatus of the present application, the opening part is provided in the region of the back cabinet body facing the display unit. An inner cylinder and the outer cylinder enclosing the inner cylinder are formed on the front surface of the peripheral edge of the opening part in the back cabinet body.

The front surface of the peripheral edge of the opening part is an inner surface of the display apparatus. The outer cylinder provided on the inner surface of the display apparatus serves as an enclosure that isolates a space inside of the opening part from the inside of the display apparatus having the possibility of fire. The inner cylinder located on the inside of the outer cylinder also serves as an additional enclosure. Therefore, a safety space for fire protection may be secured in the opening part. In addition, even when a user removes the cover body from the back cabinet and contacts the inner cylinder wall surface which is the inner peripheral surface of the opening part, safety in terms of burning of the user may be secured.

In the display apparatus according to the present application, the cover body may include a plurality of locking claws provided on the peripheral edge part of the front surface of the cover body to be locked to a peripheral wall end of the inner cylinder.

According to the display apparatus of the present application, a plurality of locking claws are provided on the peripheral edge part of the front surface of the cover body to be locked to a peripheral wall end of the inner cylinder.

When the locking claws provided on the cover body are locked to the peripheral wall end of the inner cylinder provided on the back cabinet body, the cover body is fixed to the back cabinet body around the opening part to close the opening part.

In the display apparatus according to the present application, the locking claw may have a base provided on the front surface of the cover body, and a reinforcing rib provided on a corner forming the inner surface of the base and the front surface of the cover body.

According to the display apparatus of the present application, the locking claw has a base and a reinforcing rib. The base is provided on the front surface of the cover body. The reinforcing rib is provided on the corner forming the inner surface of the base and the front surface of the cover body. The reinforcing rib serves to reinforce the base of the locking claw, thereby it is possible to increase the strength of the locking claw.

In the display apparatus according to the present application, an opening surface of the outer cylinder, the opening part and the cover body may be formed in a rectangular shape, respectively, the cover body may include a positioning protrusion which is provided on one long side surface of the cover body to position the cover body in line with the back cabinet body, the outer cylinder may include an aperture which is provided in one peripheral wall facing the positioning protrusion in a longitudinal direction of the outer cylinder to be loosely inserted into the positioning protrusion, the outer cylinder may have a guide protrusion which is provided on an inner surface of the peripheral wall of the outer cylinder around the aperture to guide the positioning protrusion into the aperture, the guide protrusion may have a concave provided on the rear surface of the guide protrusion, and the inner cylinder may be provided on the peripheral edge of the opening part including an inner periphery of the guide protrusion.

According to the display apparatus of the present application, the opening surface of the outer cylinder, the opening part and the cover body are formed in a rectangular shape, respectively. The cover body includes a positioning protrusion which is provided on one long side surface of the cover body to position the cover body in line with the back cabinet body. The outer cylinder facing the positioning protrusion includes an aperture which is provided in one peripheral wall in a longitudinal of the outer cylinder to be loosely inserted into the positioning protrusion. The one peripheral wall of the outer cylinder has a guide protrusion which guides the positioning protrusion into the aperture. The guide protrusion has a concave provided on a rear surface of the guide protrusion.

If the concave of the guide protrusion provided around the aperture of the outer cylinder guides the positioning protrusion of the cover body, the positioning protrusion may be inserted into the aperture of the outer cylinder provided on the peripheral edge of the opening part. Therefore, when the cover body is attached to the back cabinet body, it is possible to facilitate the positioning process and the attaching process of the cover body in line with the back cabinet body. Since the inner periphery of the guide protrusion is included on the peripheral edge of the opening part, the peripheral wall of the inner cylinder is inwardly overhung in the portion of the guide protrusion.

The television receiving apparatus according to the present application including: the above display apparatus; and a receiving unit which receives television broadcasts, wherein the display apparatus displays an image of the television broadcasts received by the receiving unit.

The television receiving apparatus according to the present application, the television receiving apparatus includes the above display apparatus and a receiving unit. The display apparatus displays an image of the television broadcasts received by the receiving unit. Therefore, it is possible to ensure the safety such as the fire protection, and the like, even when the back cabinet of the television receiving apparatus is divided into a plurality of members.

According to the display apparatus of the present application, it is possible to ensure the safety while dividing the casing thereof.

### BRIEF DESCRIPTION OF THE DRAWINGS

FIG. 1 is a schematic perspective view of a television receiving apparatus.

FIG. 2 is a plan view illustrating an example of an assembled display unit and a front cabinet as seen from a rear side of the television receiving apparatus.

FIG. 3 is a plan view illustrating an example of a back cabinet as seen from the rear side of the television receiving apparatus.

FIG. 4 is a schematic perspective view illustrating the example of the back cabinet.

FIG. 5A is a plan view illustrating a back cabinet body as seen from the rear side of the television receiving apparatus.

FIG. 5B is a plan view illustrating a cover as seen from the rear side of the television receiving apparatus.

FIG. 6 is a schematic perspective view illustrating an example of a back cabinet body.

FIG. 7 is a plan view illustrating an example of the cover as seen from the rear side of the television receiving apparatus.

FIG. 8 is a plan view illustrating the example of the cover as seen from a front side of the television receiving apparatus.

FIG. 9 is a schematic perspective view illustrating the example of the cover.

FIG. 10 is a schematic perspective view illustrating the example of the cover.

FIG. 11A is a plan view of a plate-shaped protrusion provided on a center of one upper long side end face of the cover.

FIG. 11B is a plan view of a plate-shaped protrusion provided near a side end of the one upper long side end face of the cover.

FIG. 12 is a schematic perspective view illustrating an example of the plate-shaped protrusion.

FIG. 13 is a partial enlarged view illustrating near a periphery of an opening part in the underside surface of the back cabinet body.

FIG. 14 is a schematic perspective view illustrating an example of a peripheral edge part of the opening part in the assembled back cabinet body and cover.

FIG. 15 is a partial enlarged view illustrating near the opening part edge in the upper side surface of the back cabinet body.

FIG. 16 is a view for explaining a state during attaching the cover to the back cabinet body.

FIG. 17A is a perspective view of a locking claw as seen obliquely from the upper right of a tip portion side thereof.

FIG. 17B is a perspective view of the locking claw as seen obliquely from the upper right of the tip portion side thereof in another angle.

FIG. 17C is a perspective view of the locking claw as seen obliquely from the upper left of a side opposite to the tip portion side.

FIG. 18 is a cross-sectional view illustrating an example of the locking claw.

FIG. 19A is a view for explaining a state before locking the locking claw of the cover to an inner cylinder of the back cabinet body.

FIG. 19B is a view for explaining a state during locking the locking claw of the cover to the inner cylinder of the back cabinet body.

FIG. 19C is a view for explaining a state in which the locking claw of the cover is locked to the inner cylinder of the back cabinet body.

FIG. 20A is a view for explaining a part of an upper side surface of the cover corresponding to the locking claw.

FIG. 20B is a view illustrating the locking claw added by a hidden double-dashed dotted line in FIG. 20A.

FIG. 21 is a partial enlarged view of a periphery of the opening part abutting the locking claw.

FIG. 22 is a view for explaining a state during assembling the back cabinet.

FIG. 23 is an enlarged view for explaining a state during assembling the back cabinet.

FIG. 24 is an enlarged view for explaining a state during assembling the back cabinet.

FIG. 25 is a view illustrating a peripheral edge part of the opening part and a peripheral edge part of the cover in the back cabinet body as seen from the front side of the television receiving apparatus.

FIG. 26 is a schematic cross-sectional view illustrating the assembled state in which a positioning rib of the cover contacts with the inner cylinder of the back cabinet body.

FIG. 27 is an enlarged view for explaining a lower peripheral edge part of the opening part.

FIG. 28A is a cross-sectional view illustrating the plate-shaped protrusion and a guide protrusion assembled to the back cabinet.

FIG. 28B is a cross-sectional view illustrating the plate-shaped protrusion and a guide protrusion assembled to the back cabinet.

FIG. 29 is an enlarged perspective view illustrating the peripheral edge part of the underside surface of the cover.

FIG. 30A is a cross-sectional view of the back cabinet body and the cover near the peripheral edge part of the opening part.

FIG. 30B is a cross-sectional view of the back cabinet body and the cover near the peripheral edge part of the opening part.

FIG. 31A is a partial enlarged view illustrating near a corner of the assembled cover.

FIG. 31B is a cross-sectional view of the back cabinet body and the cover taken on a cutting line I-I of FIG. 31A.

FIG. 32 is an enlarged plan view illustrating an example of the back cabinet body and the cover after assembling as seen from rear side of the television receiving apparatus.

FIG. 33A is a perspective view illustrating a hole formed in an upper edge part of the opening part of the back cabinet body as seen obliquely from the rear lower left of the television receiving apparatus.

FIG. 33B is a perspective view illustrating a columnar protrusion provided on the peripheral edge part of the underside surface of the cover upside as seen obliquely from the front upper right of the television receiving apparatus.

FIG. 34A is a cross-sectional view of an example of the hole and the columnar protrusion.

FIG. 34B is a perspective view illustrating the assembled back cabinet body and the cover as seen from the upper side of the cover.

FIG. 35A is a plan view illustrating the back cabinet body as seen from the rear side of the television receiving apparatus.

FIG. 35B is a plan view illustrating a cover sheet as seen from the rear side of the television receiving apparatus.

FIG. 36 is a plan view illustrating an example of the back cabinet as seen from the rear side of the television receiving apparatus.

FIG. 37A is a plan view illustrating an upper back cabinet as seen from the rear side of the television receiving apparatus.

FIG. 37B is a plan view illustrating a lower back cabinet as seen from the rear side of the television receiving apparatus.

FIG. 38A is a plan view illustrating the upper back cabinet as seen from the front side of the television receiving apparatus.

FIG. 38B is a plan view illustrating the lower back cabinet as seen from the front side of the television receiving apparatus.

FIG. 39A is a perspective view illustrating the upper back cabinet as seen obliquely from the rear lower left of the television receiving apparatus.

FIG. 39B is a perspective view illustrating the lower back cabinet as seen obliquely from the rear lower left of the television receiving apparatus.

FIG. 40 is a view for explaining a state during assembling the back cabinet.

FIG. 41A is a cross-sectional view for explaining a state before inserting a hook of the lower back cabinet into a pocket of the upper back cabinet.

FIG. 41B is a cross-sectional view for explaining a state during inserting the hook of the lower back cabinet into the pocket of the upper back cabinet.

FIG. 41C is a cross-sectional view for explaining a state in which the hook of the lower back cabinet is locked to the pocket of the upper back cabinet.

FIG. 42 is a plan view illustrating an example of the back cabinet as seen from the rear side of the television receiving apparatus.

FIG. 43 is a plan view illustrating the example of the back cabinet as seen from the front side of the television receiving apparatus.

FIG. 44 is a perspective view illustrating an example of the back cabinet as seen obliquely from the rear lower left of the television receiving apparatus.

FIG. 45 is a cross-sectional view illustrating an example of a mold for molding the back cabinet.

FIG. 46 is a view for explaining a state in which a partition part is overlapped to the back cabinet body.

FIG. 47 is a cross-sectional view illustrating another example of the mold for molding the back cabinet.

FIG. 48 is a cross-sectional view illustrating another example of the mold for molding the back cabinet.

### DETAILED DESCRIPTION

Hereinafter, a television receiving apparatus according to one embodiment of the present invention will be described in detail with reference to the accompanying drawings illustrating the embodiments thereof. The television receiving apparatus according to the present embodiment includes, for example, a flat-panel such as a liquid crystal display, a plasma display, an organic electro luminescence (EL) display, a surface-conduction electron-emitter display (SED) or the like. Hereinafter, as an example of the television receiving apparatus, a television receiving apparatus provided with the liquid crystal display will be described.

Meanwhile, the present invention is not intended to be limited to the following embodiments.

### Embodiment 1

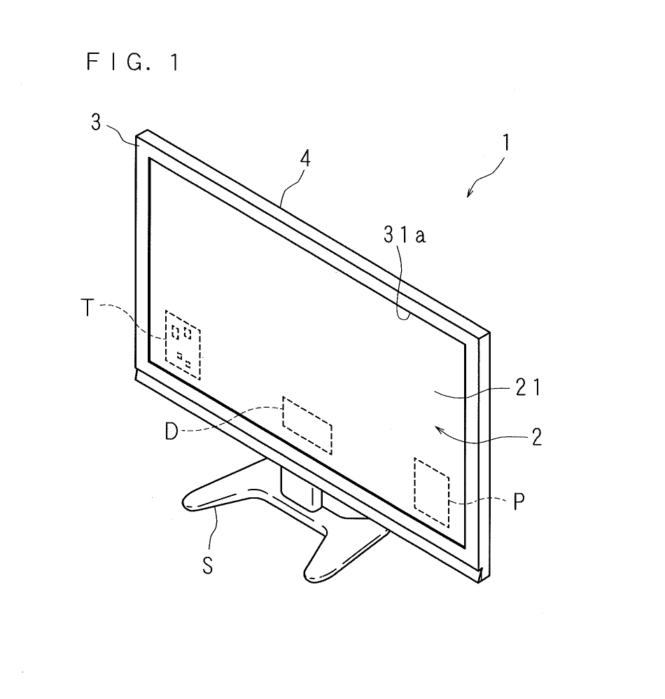

FIG. 1 is a schematic perspective view of a television receiving apparatus 1 according to the embodiment of the present invention. Herein, when a viewer faces a display surface 21 of the television receiving apparatus 1 that displays an image, the viewer side of the display surface 21 will be referred to as a front side, and the back side of the display surface 21, which is the opposite side thereof, will be referred to as a back or rear side. The display surface 21 has a laterally long and substantially rectangular shape, and from a viewer's position of facing the display surface 21, the right side of the display surface 21 in a long side direction thereof will be referred to as right, and the left side thereof in the long side direction will be referred to as left. When viewing the television receiving apparatus 1 from the rear side, the left and right sides are opposite to the left and right sides of the front side. Further, from a viewer's position of facing the display surface 21, the top side of the display surface 21 in a short side direction thereof will be referred to as upper side, and the bottom side thereof in the short side direction will be referred to as lower side. FIG. 1 illustrates the television receiving apparatus 1 as seen obliquely from the front upper right.

The television receiving apparatus 1 includes a display unit 2, a front cabinet 3, a back cabinet 4, a receiving unit T, a power board (a circuit board) P, a drive board (a circuit board) and a stand S. The display unit 2 is a liquid crystal panel module, and includes a liquid crystal panel and a backlight. The liquid crystal panel has the display surface 21 to display an image thereon. The backlight irradiates light from a rear side of the liquid crystal panel. The display unit 2 includes a front peripheral edge part and an outer peripheral surface which are enclosed by the front cabinet 3 of the front side.

The front cabinet 3 has an aperture 31a formed therein with a laterally long rectangular shape, and the display surface 21 of the display unit 2 is exposed through the aperture 31a. The back cabinet 4 of the rear side of the television receiving apparatus 1 has a substantially flat plate shape, and covers the display unit 2 and a part of the front cabinet 3 from the rear side of the television receiving apparatus 1.

The receiving unit T, the power board P and the drive board D are located between the display unit 2 and the back cabinet 4, and then fixed to the display unit 2 by screwing, for example. The stand S supports the display unit 2, the front cabinet 3, the back cabinet 4, the receiving unit T, the power board P and the drive board D in an upright state.

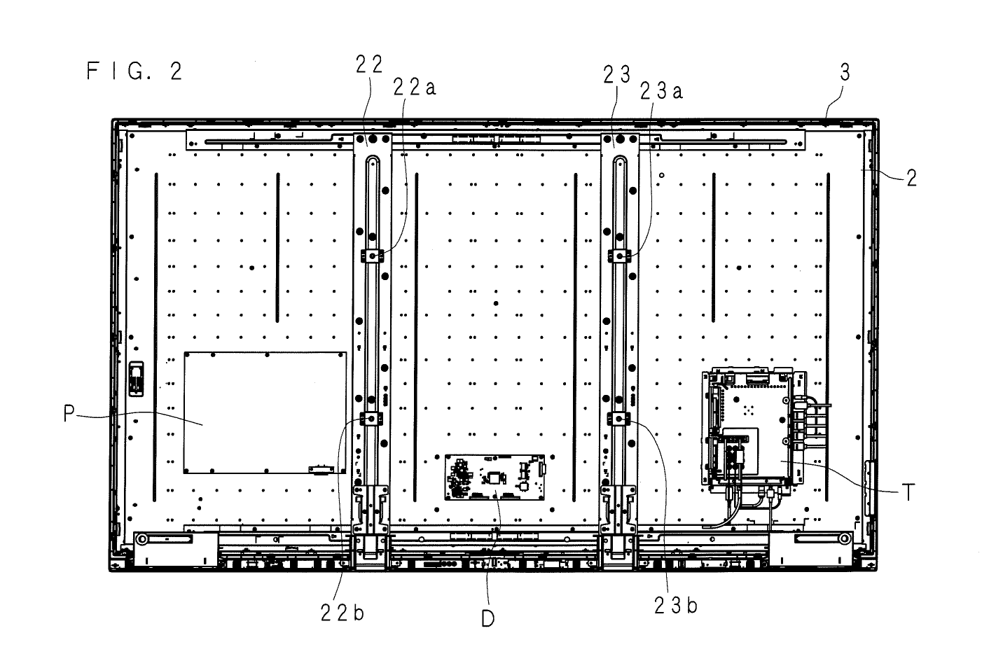

FIG. 2 is a plan view illustrating an example of the assembled display unit 2 and the front cabinet 3 as seen from the rear side of the television receiving apparatus 1. FIG. 2 illustrates the television receiving apparatus 1 from which the back cabinet 4 and the stand S are removed as seen from the rear side of the television receiving apparatus 1. Two supporting plates 22 and 23 extending in a vertical direction of the television receiving apparatus 1 are fixed to the rear side of the display unit 2 by screws, for example.

The supporting plates 22 and 23 are provided with brackets 22a, 22b, 23a and 23b having holes which are threaded for the insertion of screws therein. When the television receiving apparatus 1 is fixed to, for example, a wall of a room, the supporting plates 22 and 23 and the brackets 22a, 22b, 23a and 23b may be effectively used.

The receiving unit T receives a video signal relating to television broadcasts. The power board P supplies power to the respective components of the television receiving apparatus 1. The drive board D includes a panel drive board and a backlight drive board, for example. The panel drive board performs a prescribed signal processing on the video signal relating to the television broadcasts received by the receiving unit T, and then outputs the video signal to the liquid crystal panel after the signal processing. The backlight drive board drives the backlight.

In addition, when a flammable substance is present near the power board P and the drive board D, there is a possibility of fire from the flammable substance due to a high heat generated by a high voltage applied to the power board P and the drive board D. Herein, the power board P and the drive board D are an example of the heating element included in the television receiving apparatus 1.

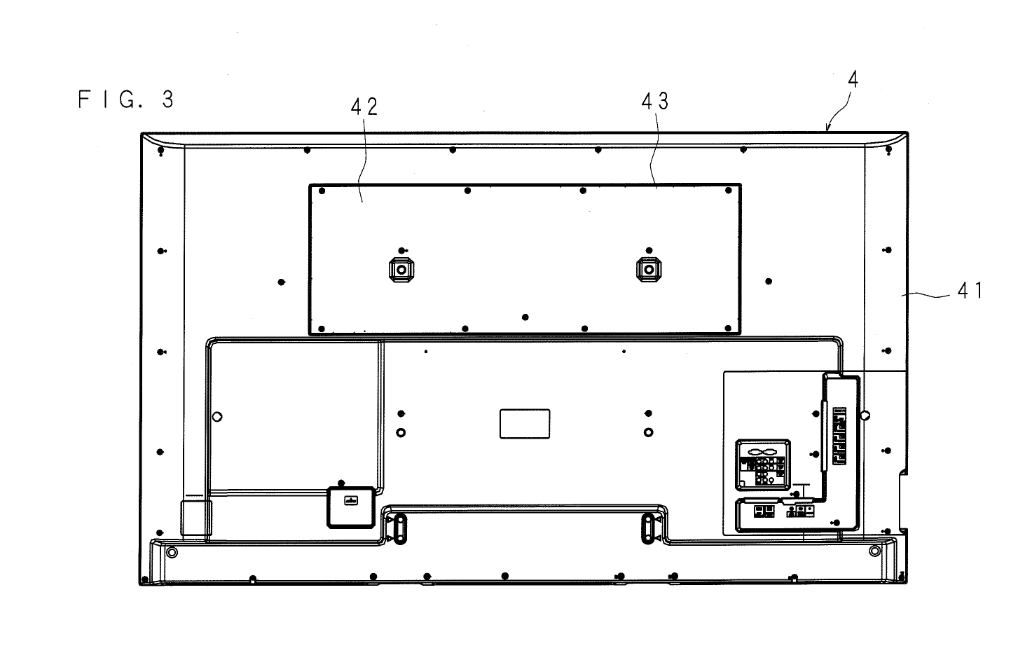

FIG. 3 is a plan view illustrating an example of the back cabinet 4 as seen from the rear side of the television receiving apparatus 1.

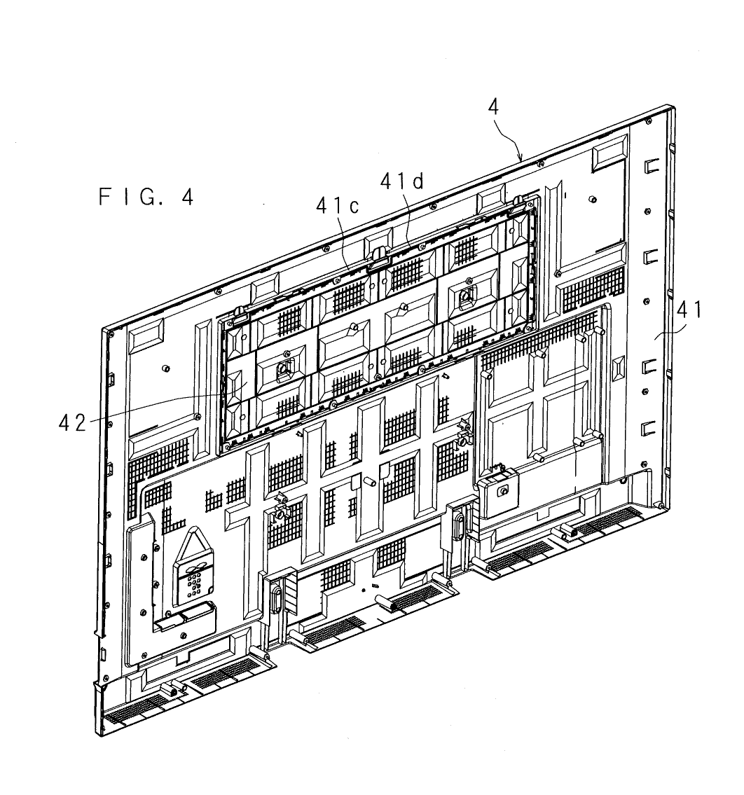

FIG. 4 is the schematic perspective view illustrating the example of the back cabinet 4. FIG. 4 illustrates the back cabinet 4 as seen obliquely from the front upper left of the television receiving apparatus 1.

The back cabinet 4 is formed as a substantially rectangular flat plate and made of a synthetic resin, for example. A plurality of screw holes are formed in an outer peripheral edge part of the back cabinet 4, thereby the back cabinet 4 may be fixed to the display unit 2 or the front cabinet 3 by screws threaded in the screw holes.

In the present embodiment, the back cabinet 4 is formed by two members. FIGS. 3 and 4 illustrate the back cabinet 4 assembled by using the two members.

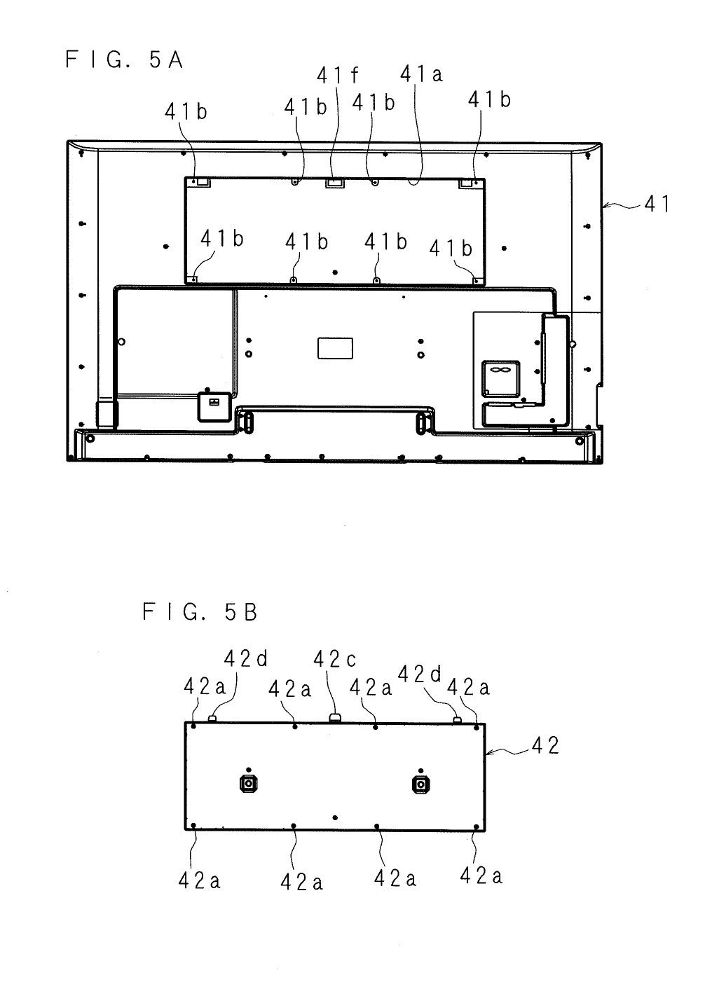

The back cabinet 4 includes a back cabinet body 41 and a cover 42 (a cover body). FIG. 5A is a plan view illustrating the back cabinet body 41 as seen from the rear side of the television receiving apparatus 1. FIG. 5B is a plan view illustrating the cover 42 as seen from the rear side of the television receiving apparatus 1. The cover 42 is provided with plate-shaped protrusions (positioning protrusions) 42c and 42d protruding upwardly from one upper long side end face thereof.

An upper side of the back cabinet body 41 and the cover 42 is referred to as the front. The upper side of the back cabinet body 41 and the cover 42 is the rear side of the television receiving apparatus 1, and an underside of back cabinet body 41 and the cover 42 is the front side of the television receiving apparatus 1.

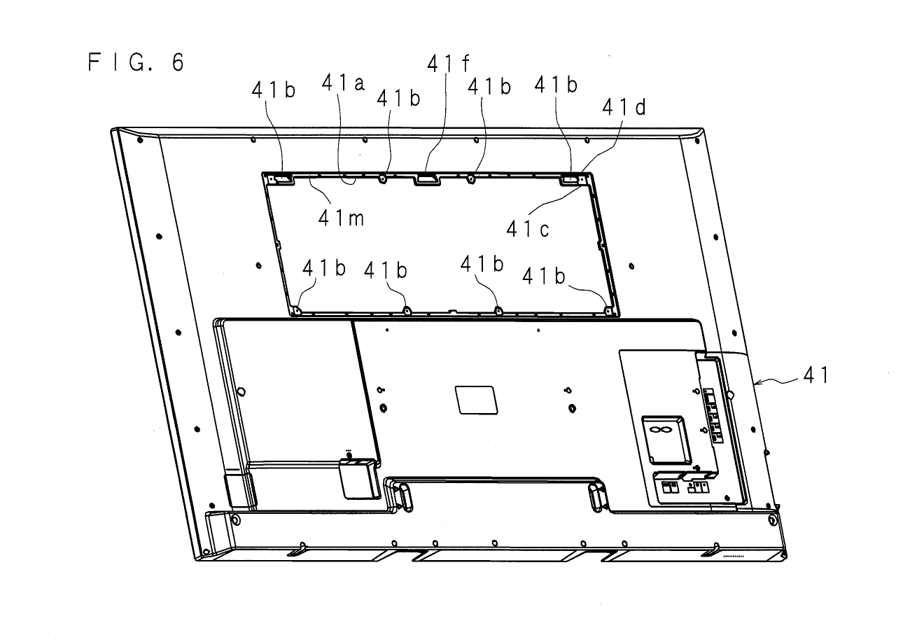

FIG. 6 is a schematic perspective view illustrating an example of the back cabinet body 41. FIG. 6 illustrates the back cabinet body 41 as seen obliquely from the rear lower left of the television receiving apparatus 1.

The back cabinet body 41 is provided with an opening part 41a in an upper center portion thereof. The region provided with the opening part 41a is a region not facing the receiving unit T, the power board P and the drive board D, for example, when the back cabinet 4 is fixed to the display unit 2 or the front cabinet 3. The opening part 41a is formed in a laterally long rectangular shape.

As illustrated in FIG. 6, a peripheral edge upper side surface of the opening part 41a is lowered into a front side (underside) of the television receiving apparatus 1 with respect to the back cabinet body 41 around an outside thereof, the peripheral edge upper side surface of the opening part 41a is a shelf 41m having a step.

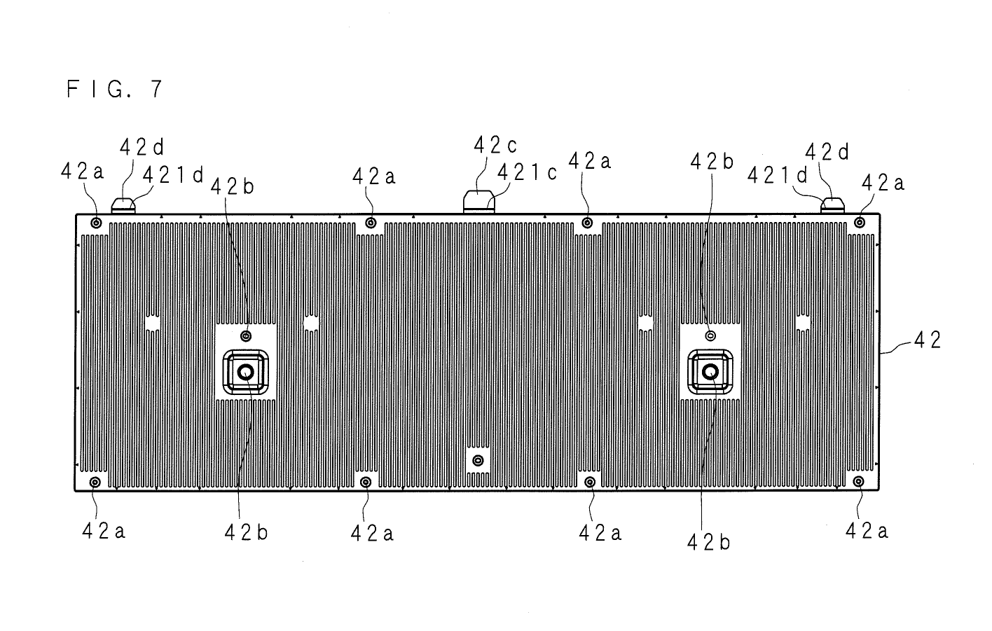

FIG. 7 is a plan view illustrating an example of the cover 42 as seen from the rear side of the television receiving apparatus 1.

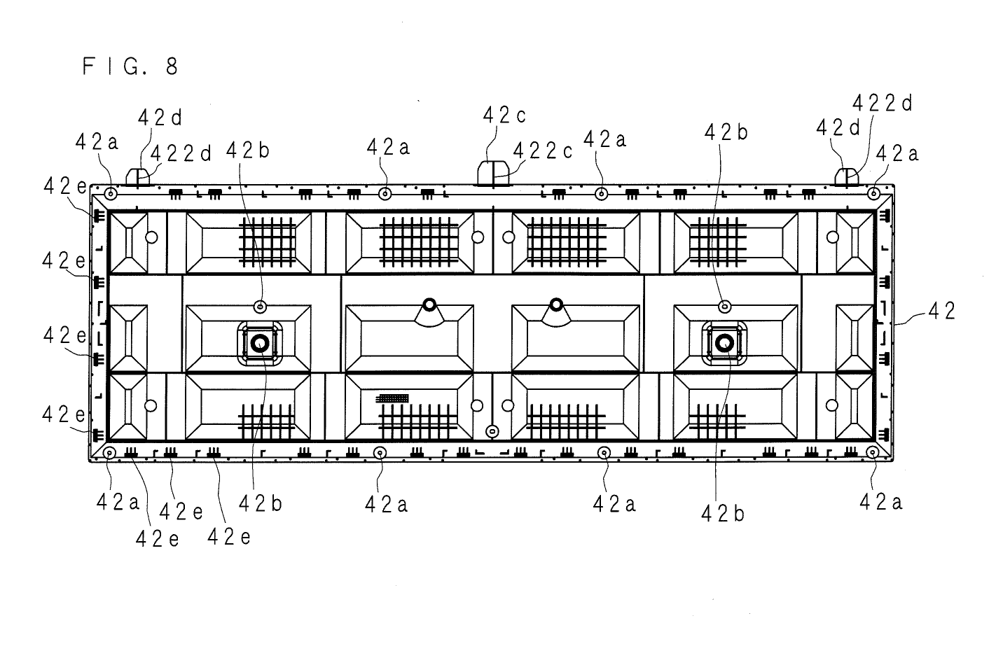

FIG. 8 is a plan view illustrating the example of the cover 42 as seen from the front side of the television receiving apparatus 1.

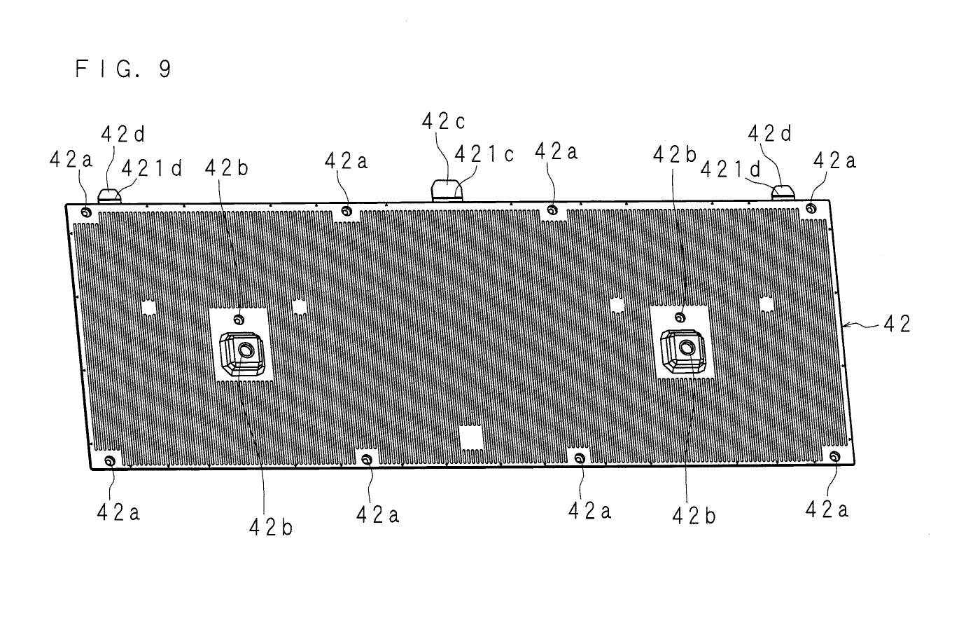

FIGS. 9 and 10 are schematic perspective views illustrating the example of the cover 42, wherein FIG. 9 illustrates the cover 42 as seen obliquely from the rear lower left of the television receiving apparatus 1, and FIG. 10 illustrates the cover 42 as seen obliquely from the front lower left of the television receiving apparatus 1.

The cover 42 is a separate part for covering the opening part 41a of the back cabinet body 41, and is a plate-shaped member formed in a rectangular shape substantially the same as the opening part 41a. The thickness of the cover 42 is substantially identical to the step of the peripheral edge part of the opening part 41a shown in FIG. 6. In addition, the size of the cover 42 is slightly smaller than the size of the opening part 41a.

Therefore, when the cover 42 is attached to the back cabinet body 41, the upper side surface (the rear side of the television receiving apparatus 1) of the back cabinet body 41 and the cover 42 forms the same plane. In addition, when the cover 42 is attached to the back cabinet body 41, a groove 43 having a small width is formed between the outer edge of the shelf 41m and the periphery of the cover 42 in the peripheral edge part of the opening part 41a of the back cabinet body 41 (see FIG. 3).

Further, the thickness of the cover 42 may be thinner than the thickness of the back cabinet body 41.

The cover 42 is temporarily jointed or fixed to the back cabinet body 41 by a claw to be described below. Further, the cover 42 may be fixed to the back cabinet body 41 by screws. Therefore, for example, eight screw through holes 42a for screwing are formed in the peripheral edge part of the cover 42 along the periphery of the cover 42.

Plate-shaped protrusions 41b facing the screw through holes 42a are protruded inward of the opening part 41a from the peripheral edge part of the opening part 41a of the back cabinet body 41 (see FIGS. 5A and 6). In the underside surface (the front side of the television receiving apparatus 1) of the protrusion 41b, bosses (not illustrated) are erected on the underside (the front side of the television receiving apparatus 1) to be screwedly connected by the screws inserted in the screw through holes 42a. The protrusion 41b provided on the corner of the opening part 41a is formed in a rectangular shape, and the protrusions 41b provided on the long side portion of the opening part 41a is formed in semicircular shape.

Four screw through holes 42b are arranged in the middle of the cover 42 so as to form respective rectangular vertices which are substantially parallel to and have a substantially similar shape with the periphery of the cover 42. Two lower screw through holes 42b are provided in a substantially center of the rectangular parallelepiped shaped protrusion protruding from the upper side surface of the cover 42. The screw through holes 42b are through holes provided to be threadedly connected with the brackets 22a, 22b, 23a and 23b of the supporting plates 22 and 23 fixed to the display unit 2 by screws.

Meanwhile, regarding the flame retardancy of a resin material, which is one of the safety standards of products and equipment, for example, 5VA, 5VB, V-0, V-1, V-2 and HB grades are defined in the UL94 standards in the order beginning with a material having the highest flame retardancy. It is necessary for a part of the products and equipment which has a potential ignition source or entails a risk of fire to be covered with, for example, an enclosure part with a flame retardancy rating of V-1 or more in terms of the UL94 standards.

In the UL94 standards, an enclosure part serves to provide fire safety, as well as mechanically and electrically separating the inside and outside of a casing. When satisfying all the following requirements, an enclosure may be certified as satisfying the UL94 standards.

A fire safety enclosure refers to an enclosure which is a part of equipment and is intended to minimize the spread of flames.

A mechanical enclosure refers to an enclosure which is a part of equipment, and is intended to reduce mechanical or other physical risks. It is one of the conditions required to prevent an object such as a clip, or the like from entering the products and equipment.

An electrical enclosure refers to an enclosure which is a part of equipment, and is intended to prevent contact with dangerous voltage and current.

The back cabinet 4 also serves as an enclosure to provide the fire, mechanical and electrical safety of the television receiving apparatus 1. Therefore, each of the back cabinet body 41 having a region facing the receiving unit T, the power board P and the drive board D and the cover 42 corresponding to a region not facing the receiving unit T, the power board P and the drive board D is made of a synthetic resin having different flame retardancy, respectively. Specifically, the back cabinet body 41 is made of a synthetic resin with a V-1 rating or more and the cover 42 is made of a synthetic resin with an HB rating or less.

In a state in which the cover 42 is removed from the back cabinet body 41, the back cabinet body 41 itself severs as an enclosure. In this case, since the cover 42 is disposed around the enclosure, the UL94 standards defined on the enclosure are not applied to the cover. Therefore, the cover 42 may be made of a material having a lower grade of flame-retardancy.

These days there is a trend for the size of the television receiving apparatus to become larger. When the television receiving apparatus 1 has a large size or an ultra large size, it is not easy for only one worker to attach the cover 42 to the back cabinet body 41. Therefore, the cover 42 and the back cabinet body 41 may be provided with a structure for facilitating the assembling work.

For example, the back cabinet body 41 can be placed on a horizontal plane such that the upper side thereof is faced upward, and then the cover 42 is placed near the opening part 41a above the back cabinet body 41. At this time, in case that the placed position of the cover 42 is shifted from the opening part 41a, when locking claws 42e, to be described below, move to a regular position while sliding on the upper side of the back cabinet body 41, there is a risk of damaging the surface of the back cabinet body 41 by means such as the locking claws 42e. Therefore, in order to guide the cover 42 to a prescribed position of the opening part 41a, the cover 42 and the back cabinet body 41 are provided with plate-shaped protrusions (the positioning protrusions) 42c and 42d, as well as a protrusion 41b and a guide protrusion 41f to be described below, respectively.

The plate-shaped protrusions 42c and 42d are protruded upwardly from the one upper long side end face of the cover 42. When the cover 42 is attached to the back cabinet body 41, by inserting the plate-shaped protrusions 42c and 42d in apertures, to be described below, formed in the back cabinet body 41, one long side of the cover 42 is easily aligned with one long side of the opening part 41a. At the same time, both short sides of the cover 42 are easily aligned with both short sides of the opening part 41a. The plate-shaped protrusion 42c is protruded on the center of the one upper long side edge face of the cover 42. Meanwhile, two plate-shaped protrusions 42d are protruded near the side edge and closer to a left corner and right corner of the cover 42, respectively.

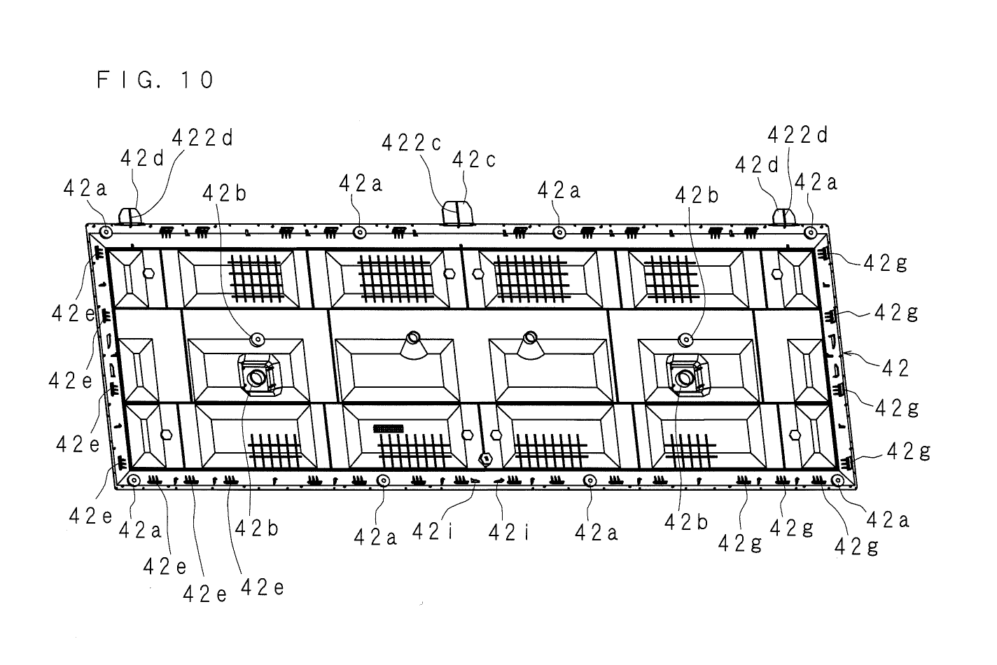

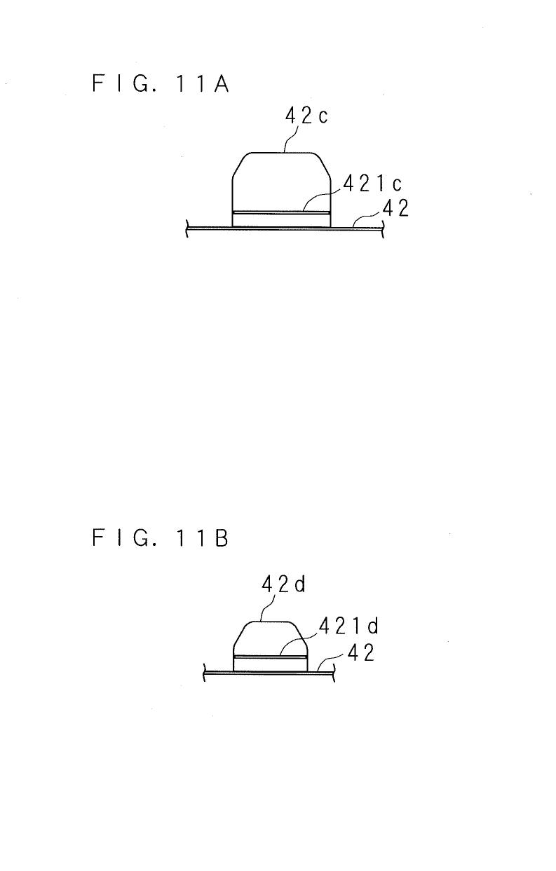

FIG. 11A is a plan view of the plate-shaped protrusion 42c provided on the center of the one upper long side end face of the cover 42.

FIG. 11B is a plan view of the plate-shaped protrusion 42d provided near the side end of the one upper long side end face of the cover 42. In FIGS. 11A and 11B, the cover 42 provided with the plate-shaped protrusion 42c and 42d is omitted except a part of the long side.

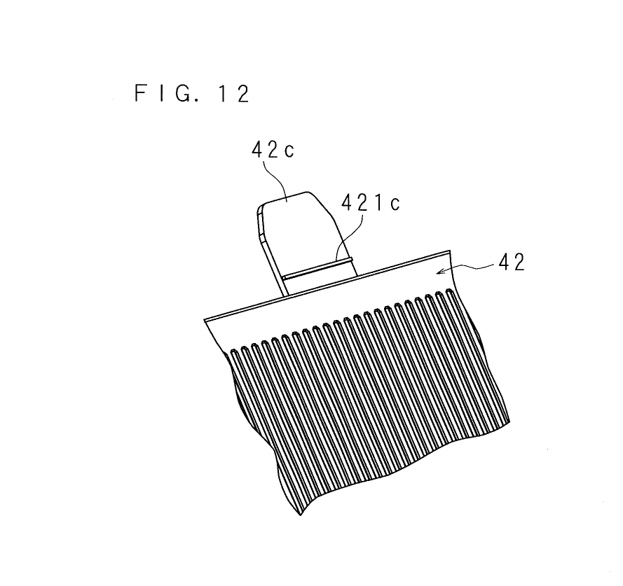

FIG. 12 is a schematic perspective view illustrating an example of the plate-shaped protrusion 42c. FIG. 12 illustrates the plate-shaped protrusion 42c as seen obliquely from the rear lower left of the television receiving apparatus 1.

The plate-shaped protrusions 42c and 42d are formed in a plate shape and have a shape obtained by cutting adjacent rectangular corners in a plan view. The plate-shaped protrusions 42c and 42d are protruded from the upper long side end face of the cover 42 so as to have the cut corners disposed on a tip side. The plate-shaped protrusion 42c is larger than the plate-shaped protrusion 42d. Therefore, in the plate-shaped protrusion 42c, both of a width substantially parallel to a longitudinal direction of the cover 42 and a length substantially parallel to a short direction of the cover 42 are longer than the width and length of the plate-shaped protrusion 42d. A base of the upper side surface (the rear side of the television receiving apparatus 1) of plate-shaped protrusions 42c and 42d is provided with one rib 421c and one rib 421d in the width longitudinal direction of the cover 42, respectively. When the plate-shaped protrusions 42c and 42d are inserted in the aperture of the back cabinet body 41, and the cover 42 is attached to the back cabinet body 41, the ribs 421c and 421d have a function to prevent entering of foreign matter into the inside of the television receiving apparatus 1 through the aperture.

Further, the tip of the plate-shaped protrusions 42c and 42d may be rounded.

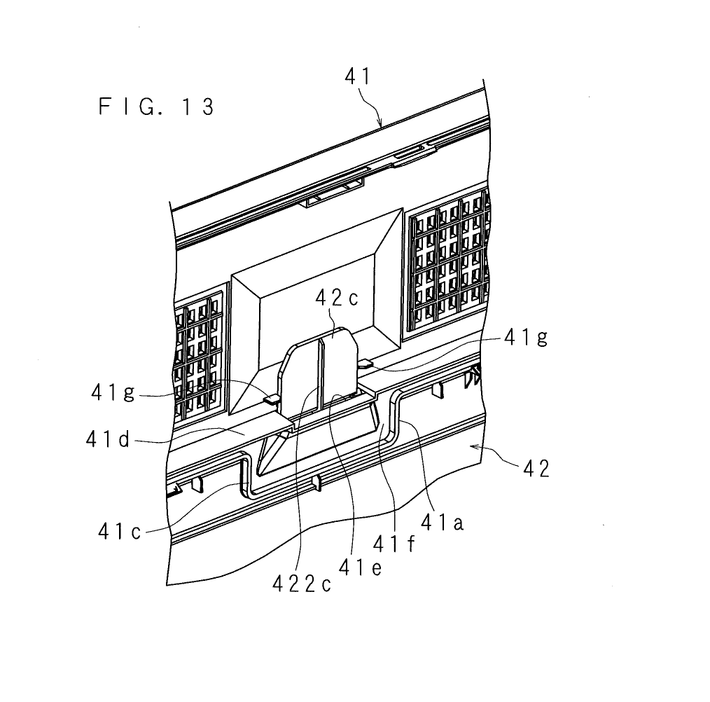

FIG. 13 is a partial enlarged view illustrating near the periphery of the opening part 41a in the underside surface of the back cabinet body 41. FIG. 13 illustrates near the center of the upper long side of the opening part 41a as seen obliquely from the front upper left of the television receiving apparatus 1. FIG. 13 illustrates a state in which the cover 42 is attached to the back cabinet body 41.

The center of the underside surface (the front side of the television receiving apparatus 1) of the plate-shaped protrusion 42c is provided with a rib 422c substantially parallel to the short direction of the cover 42. The rib 422c has a function to maintain proper strength of the plate-shaped protrusion 42c.

Further, the plate-shaped protrusions 42d are also provided with ribs 422d similar to the rib 422c (see FIGS. 8 and 10).

FIG. 14 is a schematic perspective view illustrating an example of the peripheral edge part of the opening part 41a in the assembled back cabinet body 41 and cover 42. FIG. 14 illustrates the opening part 41a of the back cabinet body 41 and the peripheral edge part of the cover 42 as seen obliquely from the front upper left of the television receiving apparatus 1.

An inner cylinder 41c and an outer cylinder 41d are erected from the underside surface of the back cabinet body 41 (the front side of the television receiving apparatus 1) in the peripheral edge part of the opening part 41a toward the front side of the television receiving apparatus 1 (see FIGS. 13 and 14). The inner cylinder 41c and the outer cylinder 41d are substantially parallel to each other. A region of the upper side surface of the back cabinet body 41 which is opposite to the inner cylinder 41c and the outer cylinder 41d, corresponds to the shelf 41m of the peripheral edge of the opening part 41a (see FIG. 6).

The inner cylinder 41c is formed to cylinder the periphery around the opening part 41a. An opening surface of the inner cylinder 41c has a substantially rectangular shape similar to the shape of the opening part 41a. Rectangular or semicircular-shaped protrusions 41b to erect the bosses for screwing are protruded from the inner peripheral surface of the outer cylinder 41d, and the inner cylinder 41c is isolated from the outer cylinder 41d or overhung inward of the opening part 41a in the portion of the protrusions 41b.

The outer cylinder 41d is disposed on the outside of the inner cylinder 41c surrounding the same. The height of the peripheral wall of the outer cylinder 41d is higher than the height of the peripheral wall of the inner cylinder 41c. The outer cylinder 41d servers as an enclosure for the cover 42.

Notches (not illustrated) are formed in the peripheral wall portion of the outer cylinder 41d facing the supporting plates 22 and 23 of the display unit 2. Notches house the supporting plates 22 and 23 overhung to the rear side of the television receiving apparatus 1.

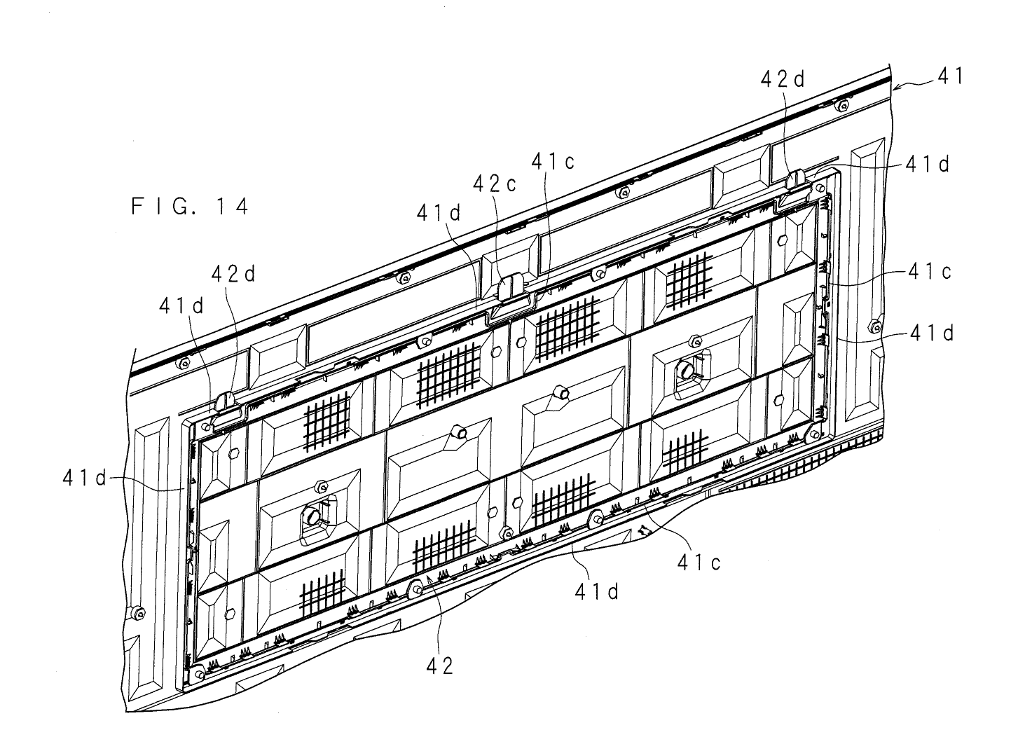

FIG. 15 is a partial enlarged view illustrating near the periphery of the opening part 41a in the upper side surface of the back cabinet body 41. FIG. 15 illustrates near the center of the upper long side of the opening part 41a as seen obliquely from the rear lower left of the television receiving apparatus 1.

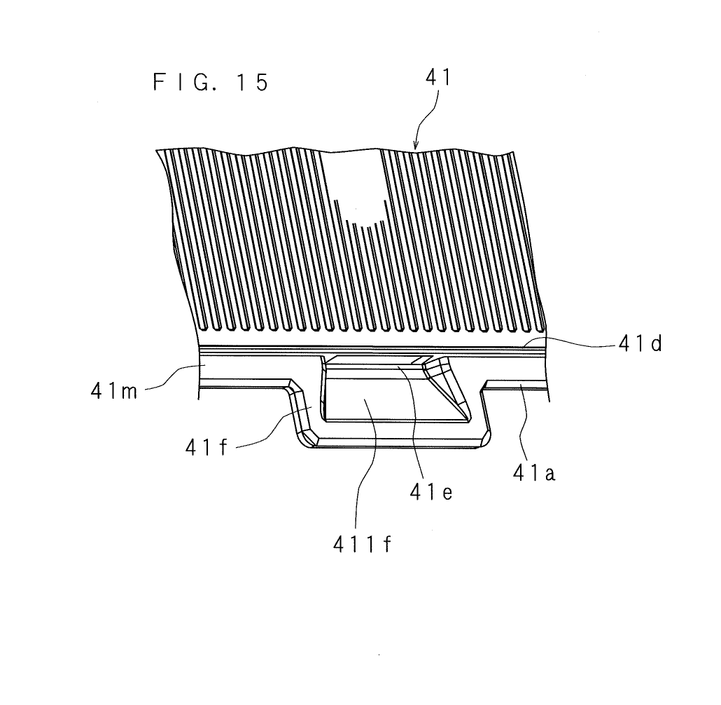

FIG. 16 is a view for explaining the state during attaching the cover 42 to the back cabinet body 41. FIG. 16 illustrates near the center of the upper long side of the opening part 41a as seen obliquely from the rear lower left of the television receiving apparatus 1.

An aperture 41e is disposed in a position of the outer cylinder 41d facing the plate-shaped protrusions 42c and 42d. The aperture 41e is formed in a laterally long rectangular shape. The long side of the aperture 41e facing the plate-shaped protrusion 42c is longer than the width of the plate-shaped protrusion 42c, and the short side of the aperture 41e facing the plate-shaped protrusion 42c is longer than the thickness of the plate-shaped protrusion 42c. Therefore, the plate-shaped protrusion 42c can be loosely inserted in the aperture 41e. Similarly, the plate-shaped protrusion 42d is also configured to loosely insert into the aperture 41e facing thereto.

A guide protrusion 41f is protruded on the center of one upper peripheral wall of the outer cylinder 41d. The guide protrusion 41f receives the plate-shaped protrusions 42c and 42d and guide the received plate-shaped protrusions 42c and 42d into the aperture 41e. Therefore, the inner cylinder 41c is also overhung inward of the opening part 41a on the portion of the guide protrusion 41f, so that the inner cylinder 41c is overhung inward of the opening part 41a on the portion of the protrusions 41b.

A concave 411f recessing to the front side of the television receiving apparatus 1 toward the outer cylinder 41d from the tip portion of the guide protrusion 41f, is formed on the rear side surface of the guide protrusion 41f. The inner wall of the concave 411f on the outside is formed as the peripheral wall of the outer cylinder 41d, and the aperture 41e is formed in the substantially center of the inner wall of the concave on the outside 411f. The bottom of the concave 411f is formed in a plane shape and inclined uniformly toward the outer cylinder 41d from the tip of the guide protrusion 41f. In addition, the bottom portion of the concave 411f is extended toward the inside end from the aperture 41e. Alternatively, the bottom portion of the concave 411f is narrower toward the aperture 41e from the inside end. That is, in order to guide the plate-shaped protrusion 42c to the aperture 41e, the bottom of the concave 411f is converged towards the aperture 41e. The bottom of the concave 411f is formed in a trapezoidal shape having an upper base shorter than the lower base in a plan view, and the upper base thereof is consistent with the aperture 41e formed in the outer cylinder 41d. The substantial shape of the concave 411f is similar to a dustpan.

The protrusion 41b corresponding to the plate-shaped protrusion 42d is provided on the both upper corner portions of the opening part 41a in the back cabinet body 41, such that the guide protrusion 41f is provided on the back cabinet body 41 corresponding to the plate-shaped protrusion 42c (see FIGS. 5A and 6). The plate-shaped protrusions 41b are formed in the same shape as the guide protrusion 41f and have the same function.

Further, in order to fix the cover 42 to the back cabinet body 41, the plate-shaped protrusions 41b corresponding to the plate-shaped protrusions 42d may be the plate-shaped protrusions 41b for erecting the bosses (not illustrated) (see FIGS. 5A and 6).

As illustrated in FIG. 13, two positioning ribs 41g are erected slightly outside from the center aperture 41e formed in the outer cylinder 41d of the back cabinet body 41 toward the front side of the television receiving apparatus 1. In order to correctly insert the plate-shaped protrusion 42c in the aperture 41e, the positioning ribs 41g have a function to position the cover 42 in line with the back cabinet body 41 during an inserting process.

As illustrated in FIGS. 8 and 10, the locking claws 42e are formed on the peripheral edge part of the cover 42 underside surface (the front side of the television receiving apparatus 1). In this embodiment, a total of thirty-two locking claws 42e, for example, four locking claws along each of the short side of the cover 42, ten locking claws along the upper long side of the cover 42, and fourteen locking claws along the lower long side of the cover 42, are provided. The tip portions of the locking claws 42e face the outside of the cover 42. Therefore, the tip portions of locking claws 42e provided along the facing long sides of the cover 42 are mutually oppositely oriented. Similarly, the tip portions of locking claws 42e provided along the facing short sides of the cover 42 are mutually oppositely oriented.

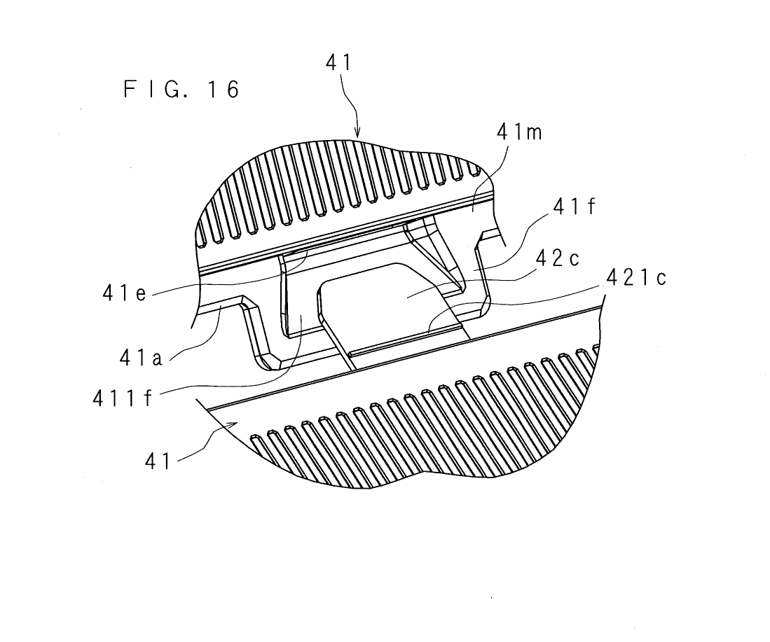

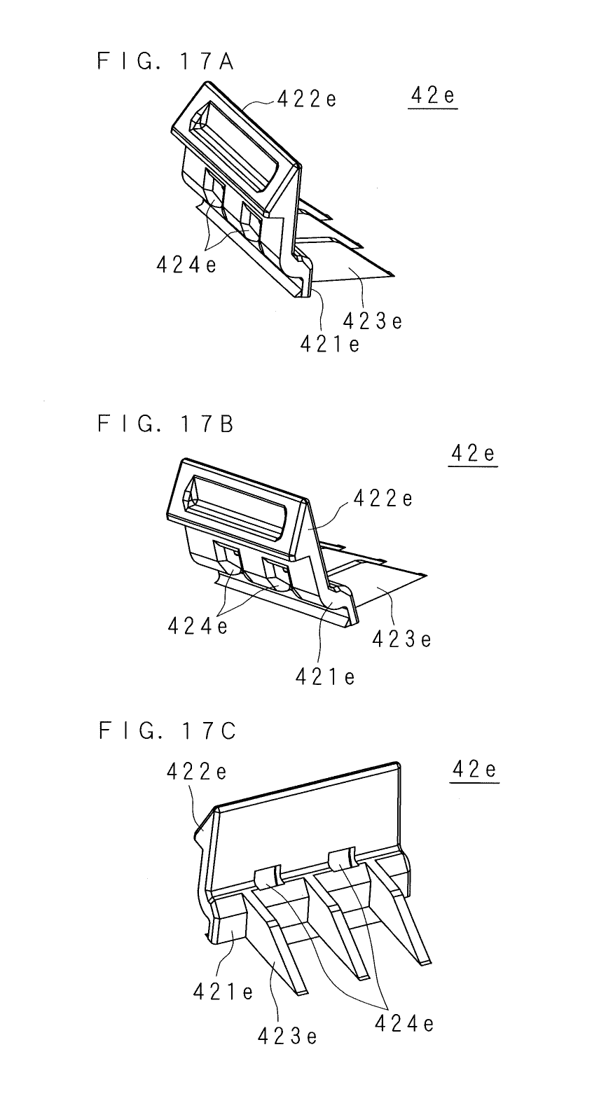

FIGS. 17A and 17B are perspective views of the locking claw 42e as seen obliquely from the upper right of the tip portion 422e side thereof in different angles with respect to each other. FIG. 17C is a perspective view of the locking claw 42e as seen obliquely from the upper left of an opposite side to the tip portion 422e.

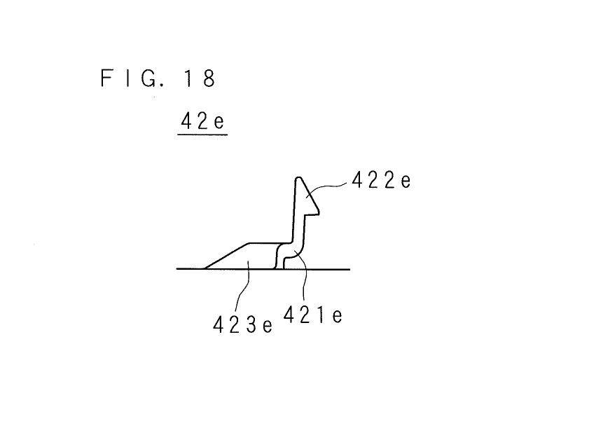

FIG. 18 is a cross-sectional view illustrating an example of the locking claw 42e. FIG. 18 is a cross-sectional view of the locking claws 42e provided along the long side of the cover 42 taken by cutting in a sectional plane parallel to a normal line and the short side of the cover 42, for example.

The locking claw 42e includes a bent plate portion (a base) 421e, a tip portion 422e and a reinforcing rib 423e.

For example, the bent plate portion 421e of the locking claw 42e provided along the long side of the cover 42 is formed in a rectangular shape as seen in a short side direction of the cover 42, and is formed in a crank shape having a step portion bending to outside of the cover 42 as seen in a long side direction of the cover 42. For example, two square shape slits 424e are opened in the locking claws 42e above from a bent portion of the bent plate portion 421e. Further, the shape of the slit 424e is not limited to a square shape, and for example, the slit 424e may be formed in a rectangular shape. The bent plate portion 421e is formed along the periphery to the peripheral edge part of an underside surface of the cover 42. Preferably, the bent plate portion 421e is formed in a position corresponding to the inner cylinder 41c of the back cabinet body 41, when the cover 42 is attached to the back cabinet body 41. The tip end portion 422e is formed on the apical face of the bent plate portion 421e.

The tip end portion 422e is formed in a triangle prismatic-shaped pawl elongated in a circumferential direction of the cover 42. The tip end portion 422e is formed so as to contact the triangle prismatic side thereof with the apical face of the bent plate portion 421e.

The reinforcing rib 423e is formed in a trapezoidal shape in a plan view in the circumferential direction of the cover 42, and is formed on a corner forming the cover 42 underside surface and the inner surface of the base of the bent plate portion 421e. The height of the reinforcing rib 423e from an underside surface of the cover 42 is equal to the height of the bent portion of the bent plate portion 421e from 42 an underside surface of the cover 42, for example.

The locking claw 42e has three reinforcing ribs 423e disposed at equal intervals, and two slits 424e formed in positions corresponding to between the reinforcing ribs 423e.

When the plate-shaped protrusions 42c and 42d of the cover 42 are inserted into the apertures 41e, the cover 42 is aligned with the back cabinet body 41. Thereafter, the cover 42 is temporarily jointed or fixed to the back cabinet body 41 using the locking claws 42e provided on the cover 42, and then the cover 42 is attached to the back cabinet body 41 by screwing.

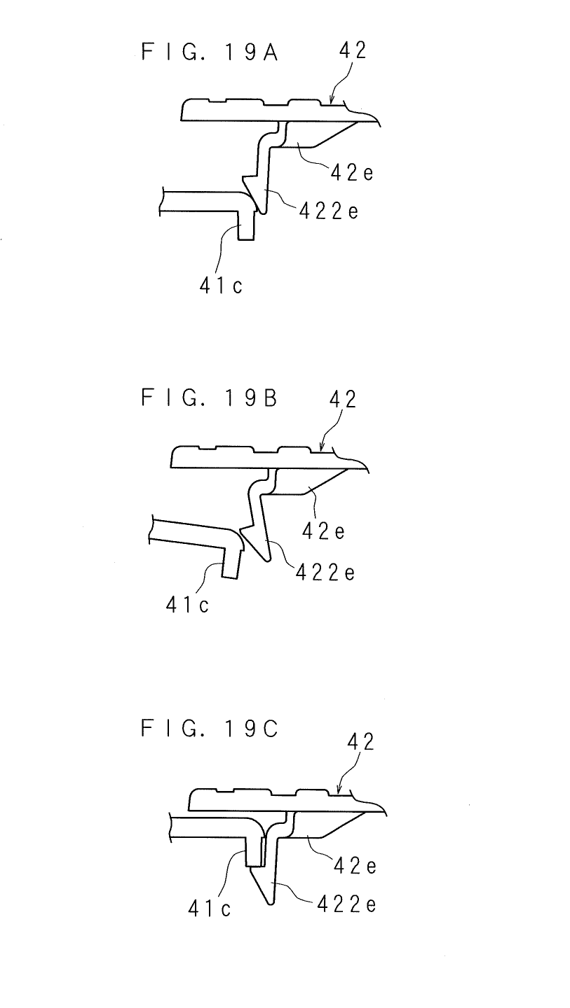

FIGS. 19A, 19B and FIG. 19C are views for explaining the state in which the locking claw 42e of the cover 42 is locked to the inner cylinder of the back cabinet body 41, before, during and after locking, respectively. When attaching the cover 42 to the back cabinet body 41, a worker presses the upper side surface of the cover 42 (the rear side of the television receiving apparatus 1), such that the outward pawl of the locking claw 42e is locked to the peripheral wall end face of the inner cylinder 41c provided on the peripheral edge of the opening part 41a of the back cabinet body 41.

That is, if the worker presses the upper side surface of the cover 42, the tip end portion 422e of the cover 42 presses the periphery of the opening part 41a including the inner cylinder 41c (FIG. 19A). The pressed periphery of the opening part 41a is bent forward and outward of the television receiving apparatus 1, and the locking claws 42e are also elastically deformed inward of the television receiving apparatus 1 (FIG. 19B). When the tip end portion 422e of the cover 42 is further moved forward of the television receiving apparatus 1 from the peripheral wall end face of the inner cylinder 41c, the pawl of the tip end portion 422e is locked to the peripheral wall end face of the inner cylinder 41c, thereby fixing the cover 42 to the back cabinet body 41 (FIG. 19C).

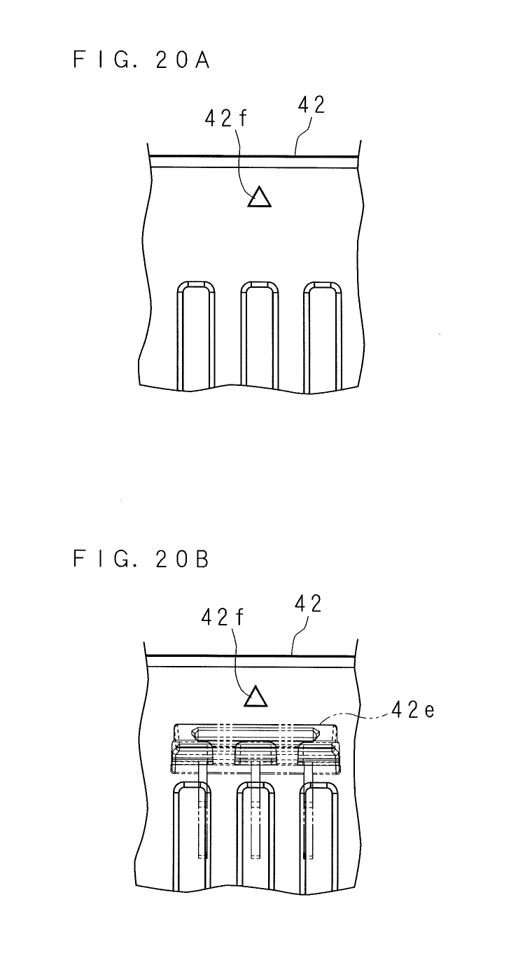

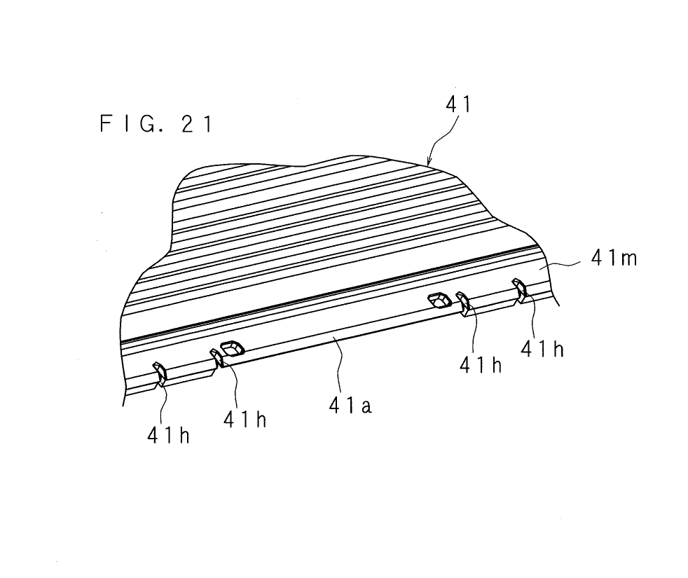

FIG. 20A is a view for explaining a part of an upper side surface of the cover 42 corresponding to the locking claw 42e. FIG. 20B is a view illustrating the locking claw 42e added by a hidden double-dashed dotted line in FIG. 20A. A triangle (Δ) mark 42f is formed slightly outside from a position corresponding to the locking claws 42e in an upper side surface of the cover 42.

The locking claws 42e cannot be seen from the upper side of the cover 42. However, the worker may press the upper side surface portion of the cover 42 corresponding to the locking claw 42e by using the triangle (Δ) mark 42f as a guide, thereby the locking claws 42e can be locked to the back cabinet body 41.

FIG. 21 is a partial enlarged view of the periphery of the opening part 41a abutting the locking claw 42e. FIG. 21 illustrates the periphery of the opening part 41a as seen obliquely from the rear lower left of the television receiving apparatus 1.

The periphery of the opening part 41a abutting the locking claws 42e is provided with a total of two notches 41h on both sides of the portion abutting the locking claws 42e, respectively. In order to lock the locking claws 42e to the peripheral wall end face of the inner cylinder 41c, it is necessary for the inner peripheral portion of the opening part 41a to be elastically deformed. When the degree of elastic deformation in the periphery of the opening part 41a is small, fixing of the cover 42 to the back cabinet body 41 is difficult. In some cases, since the amount of the elastic deformation of the periphery of the opening part 41a is also taken up by the locking claws 42e, the locking claws 42e may be damaged. In this regard, the notches 41h have a function to easily bend the periphery of the opening part 41a. Therefore, it is possible to attach the cover 42 to the back cabinet body 41 without applying an excessive force to the locking claws 42e.

Next, an assembling method of the back cabinet 4 will be described.

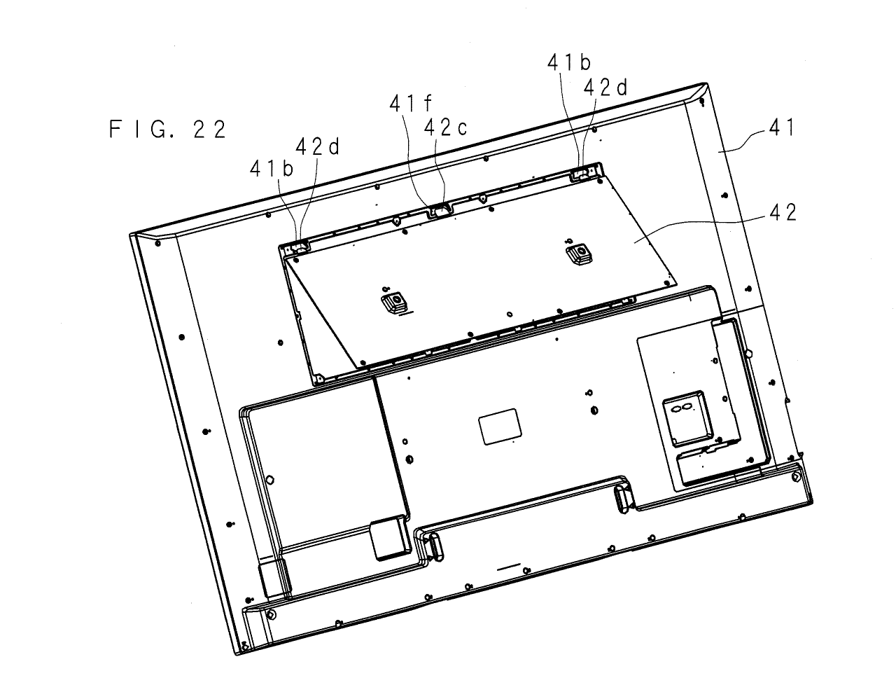

FIG. 22 is a view for explaining a state during assembling the back cabinet 4. The back cabinet body 41 is placed on a horizontal plane such that the upper side thereof is faced upward. The cover 42 is held with both hands such that the plate-shaped protrusions 42c and 42d are located toward the front, the upper side of the cover 42 is faced upward, and the cover 42 is located substantially horizontal. Then, the cover 42 is moved to a position in which the plate-shaped protrusions 42c and 42d face the guide protrusion 41f and plate-shaped protrusions 41b of the back cabinet body 41, respectively. In this case, the long side of the opening part 41a and the long side of the cover 42 are substantially parallel to each other, and the short side of the opening part 41a and the short side of the cover 42 also are substantially parallel to each other.

The one long side of the cover 42 (a front side long side of the cover 42) is lifted around other long side of the cover 42 provided with plate-shaped protrusions 42c and 42d, such that the cover 42 is inclined to the upper side surface of the back cabinet body 41 (the horizontal plane). Preferably, an inclined angle of the cover 42 in this case is close to the inclined angle of the bottom of the concave 411f provided in the guide protrusion 41f and the protrusion 41b of the back cabinet body 41. Then, the plate-shaped protrusions 42c and 42d are slowly inserted into the aperture 41e formed in the outer cylinder 41d, that is, the aperture 41e of deepest region of the concave 411f.

In this case, since the center plate-shaped protrusion 42c is longer than the plate-shaped protrusions 42d of both sides, the center plate-shaped protrusion 42c is firstly inserted into the concave 411f of the guide protrusion 41f, and then the plate-shaped protrusions 42d of both sides are inserted into the concaves 411f of the protrusion 41b. Next, the center plate-shaped protrusion 42c is firstly inserted into the aperture 41e, and then the plate-shaped protrusions 42d of both sides are inserted into the aperture 41e. Accordingly, the worker can finish without the difficult task of simultaneously inserting the three plate-shaped protrusions 42c and 42d into the aperture 41e. Further, since the positioning ribs 41g for positioning in the lateral direction are provided behind the aperture 41e in which the center plate-shaped protrusion 42c is inserted, the plate-shaped protrusion 42c is guided by the two positioning ribs 41g. Thereby, the positioning of the cover 42 relative to the long side direction (the lateral direction) and the short side direction of the opening part 41e may be almost completed.

When the one long side of the cover 42 is slowly pivoted downward around the other long side of the cover 42 provided with the plate-shaped protrusions 42c and 42d, the inclined angle of the cover 42 becomes gradually reduced. The locking claws 42e of the cover 42 abuts the periphery of the opening part 41a. Then, the worker presses the upper side surface of the cover 42 using the triangle mark 42f formed on the upper side surface of the cover 42 as a guide. Moving the pressing portion along the peripheral edge of the cover 42, the pawl of all the locking claws 42e are locked to the peripheral wall end face of the inner cylinder 41c, thereby the cover 42 is fixed to the back cabinet body 41. In this case, the back cabinet 4 is provided with a structure for accurately positioning the cover 42 in line with the back cabinet body 41.

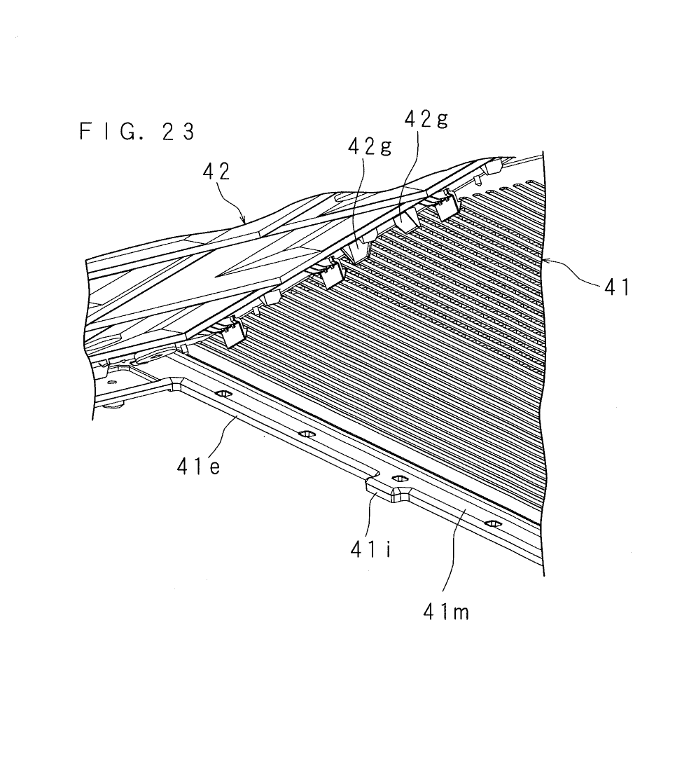

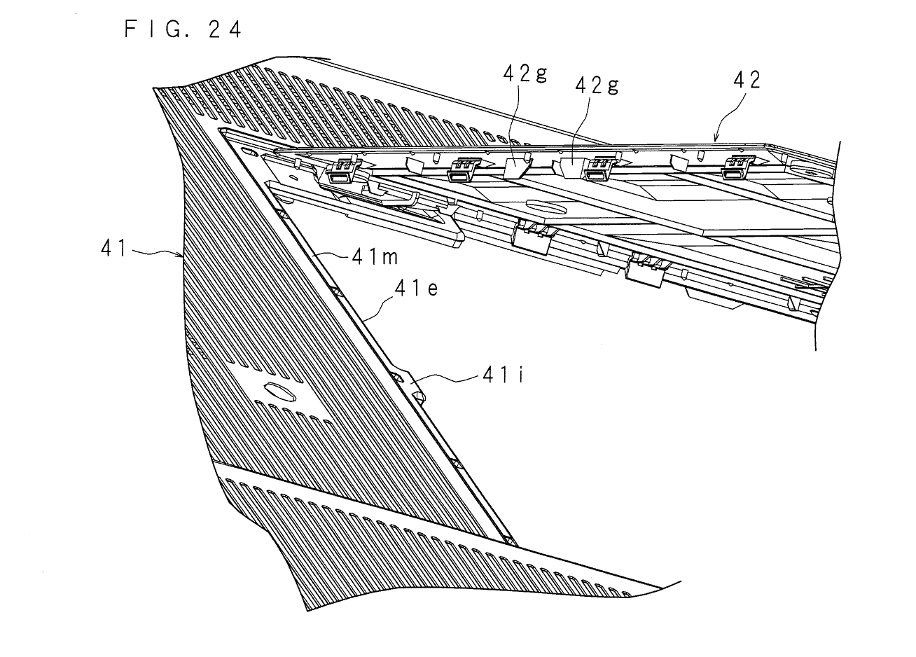

FIGS. 23 and 24 are enlarged views for explaining the state during assembling the back cabinet 4. FIGS. 23 and 24 are views for explaining the assembling of the cover 42 to the back cabinet body 41. FIG. 23 is an enlarged view illustrating a upper right part of the back cabinet 4, and FIG. 24 is an enlarged view illustrating a upper left part of the back cabinet 4.

A rectangular-shaped protrusion 41i is provided in the center of the short side end face of the opening part 41a, respectively. In addition, the peripheral surface of the opening part 41a is the same as the inner peripheral surface of the inner cylinder 41c. Meanwhile, in order to attach the cover 42 to the back cabinet body 41, two guide ribs 42g are provided in the center of the left and right short side edge portion of the underside surface of the cover 42. The two guide ribs 42g may be provided so as to be loosely fitted away from the protrusion 41i.

When pressing the upper side surface of the cover 42 in accordance with the short side of the cover 42 to the short side of the opening part 41a, due to the guide ribs 42g provided on the left and right by each guide protrusions 41i, the cover 42 is positioned with respect to the short side direction of the opening part 41a.

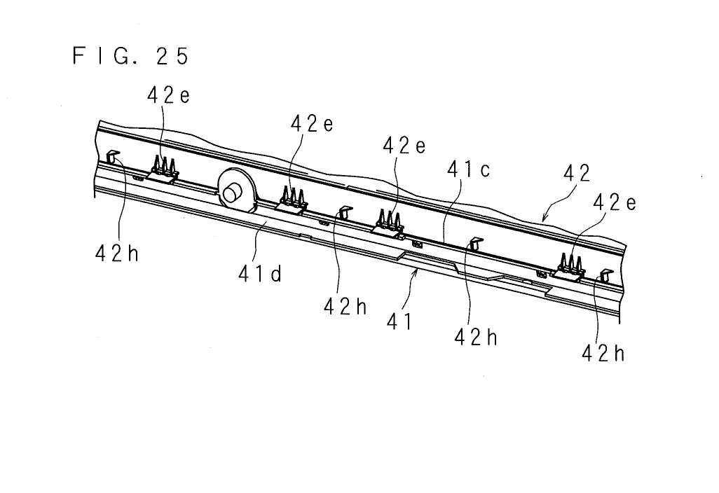

FIG. 25 is a view illustrating the peripheral edge part of the opening part 41a and the peripheral edge part of the cover 42 in the back cabinet body 41 as seen from the front side of the television receiving apparatus 1. FIG. 25 is an enlarged view illustrating near the lower portion of the opening part 41a in the back cabinet body 41 assembled with the cover 42. The peripheral edge part of the underside surface of the cover 42 is provided with positioning ribs 42h. For example, ten positioning ribs 42h are disposed on positions corresponding to the lower long side of the cover 42 at substantially equal intervals. The positioning ribs 42h are provided near the inner peripheral surface of the inner cylinder 41c of the back cabinet body 41.

For example, eleven similar positioning ribs 42h are provided on positions corresponding to the upper long side of the cover 42.

When pressing the upper side surface of the cover 42 in accordance with the long side of the opening part 41a of the cover 42, since the positioning ribs 42h guide the inner cylinder 41c of the back cabinet body 41, the cover 42 is positioned with respect to the short side direction of the opening part 41a.

FIG. 25 also illustrates the locking claws 42e. The locking claws 42e are locked to the peripheral wall end of the inner cylinder 41c provided on the underside surface of the back cabinet body 41 in the peripheral edge part of the opening part 41a. The locking claws 42e have a function to fix the cover 42 to the back cabinet body 41.

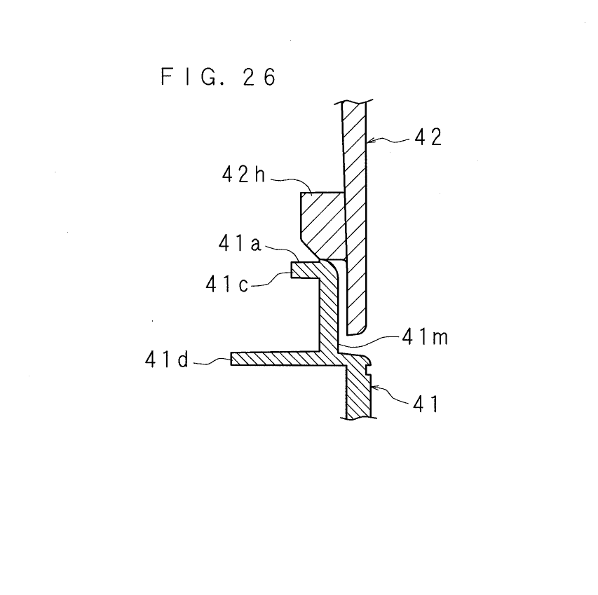

FIG. 26 is a schematic cross-sectional view illustrating the assembled state of the back cabinet body 41 and the cover 42. FIG. 26 is a cross-sectional view of near the lower long side of the opening part 41a taken by cutting in a sectional plane parallel to the normal line of the cover 42 and the short side of the cover 42. In the example of FIG. 26, by abutting the positioning ribs 42h the base of the inner cylinder 41c, the cover 42 is controlled so as not to move downward.

Further, the positioning ribs 42h may be provided at positions corresponding to the left and right short side of the cover 42. In this case, the cover 42 is positioned with respect to the long side direction thereof (the lateral direction).

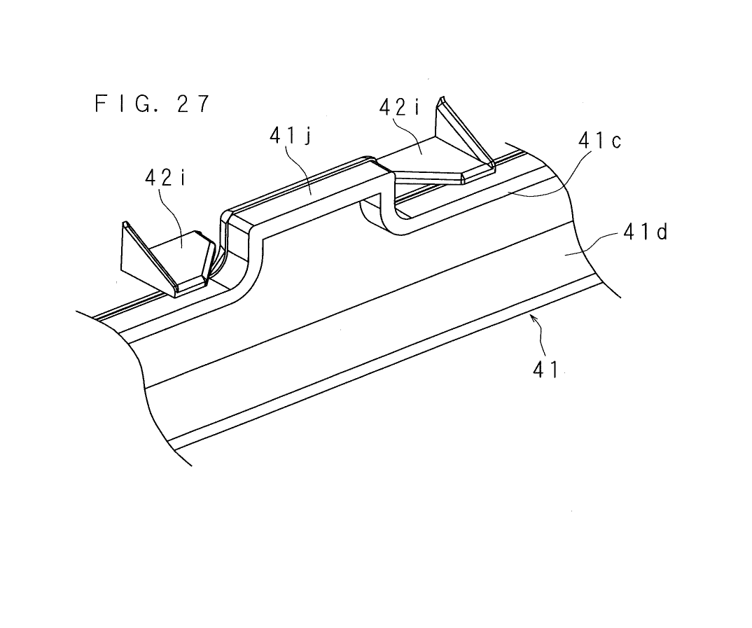

FIG. 27 is an enlarged view for explaining the lower peripheral edge part of the opening part 41a. FIG. 27 is a partial enlarged view of near the center of the lower long side of the opening part 41a with respect to the assembled state of the back cabinet body 41 and the cover 42, as seen obliquely from the front upper left of the television receiving apparatus 1.

The rectangular-shaped protrusion 41j is protruded from the peripheral surface of the inner cylinder 41c in the center of the lower long side of the opening part 41a. Meanwhile, when the cover 42 is attached to the back cabinet body 41, two guide ribs 42i are provided near the center of the lower long side of the underside surface of the cover 42 facing the protrusion 41j. The two guide ribs 42i may be provided so as to be loosely fitted away from the protrusion 41j. In FIG. 27, parts of the cover 42 other than the guide ribs 42i are omitted. Further, parts of the back cabinet body 41 other than the peripheral edge part of the opening part 41a also are omitted.

When pressing the upper side surface of the cover 42 in accordance with the long side of the cover 42 to the long side of the opening part 41a, the guide ribs 42i provided near the center of the lower long side of the cover 42 guide the protrusions 41j. When the cover 42 is pivoted around the normal direction of the cover 42 with respect to the back cabinet body 41, the position of the cover 42 may be shifted by the rotation. However, in this embodiment, a shift in a position of the cover 42 in a rotating direction around the normal direction of the cover 42 can be controlled by the plate-shaped protrusions 42c and 42d inserted in the aperture 41e of the back cabinet body 41. Further, a shift in a position of the cover 42 in a rotating direction around the normal direction of the cover 42 can be controlled by the protrusions 41j and guide ribs 42i. Therefore, the protrusions 41j and guide ribs 42i contribute to the positioning of the cover 42 in the rotating direction around the normal direction of the cover 42.

When the positioning of the cover 42 to the back cabinet body 41 is completed, screws are inserted in the screw through holes 42a. Then, the inserted screws are threaded in the screw holes of the bosses provided on the protrusion 41b of the back cabinet body 41, thereby the cover 42 is fixed to the back cabinet body 41.

According to the above-described television receiving apparatus 1, it is possible to ensure safety while dividing a casing thereof.

When the cabinet is made of a synthetic resin used in a large-sized thin display device, since a required clamping force is increased as the projected area increases, a larger molding machine is needed. However, in some cases, it is not possible to provide a larger molding machine. In addition, since a cost for operating the larger molding machine increases, overall costs may increase. However, if the cabinet is divided into a plurality of members, it is possible to mold the cabinet using a conventional molding machine.

Meanwhile, safety relating to flammability is required in electrical products. Therefore, for example, flame retardant material with a V-1 rating is used for the material of the cabinet. However, the price of flame retardant material is expensive as the flammability rating is high. Therefore, a low grade flame retardant material is used for members of the parts isolated by a member forming the enclosure.

Specifically, the cabinet is divided into a cabinet part covering the circuit board portion to which a high voltage is applied and a part with no cabinet portion. When the latter is formed as a separate piece from the cabinet, a material having a low flame retardancy may be used for the separate piece isolated by the former which is an enclosure. Thereby, it is possible to reduce the cost, while the safety of fire protection is ensured.

An enclosure has a function to prevent mechanical risk, prevention of electric shock, prevention of electromagnetic interference, as well as providing dust-proofing, waterproofing, airtightness, heat insulation, explosion-proofing, or the like in addition to the fire prevention. Therefore, materials with different properties with respect to features of these enclosures may be used for each divided cabinet part.

In the television receiving apparatus 1, the back cabinet 4 is divided into two pieces of the back cabinet body 41 and the cover 42. The back cabinet body 41 may have the opening part 41a in the region not facing the power board P, the drive board D and the like. Even when a material having a low flame retardancy is used to mold the cover 42 covering the opening part 41a, as long as the back cabinet body 41 is molded from a material having a high flame retardancy, safety in terms of fire protection may be secured.

In addition, the back cabinet body 41 may have the opening part 41a in the region facing the power board P, the drive board D and the like. In this case, material having a high flame retardancy or material having a low electrical conductivity is used for the cover 42 covering the opening part 41a. On the other hand, material having a low flame retardancy or material having a low electrical conductivity is used for the back cabinet body 41. By this, it is also possible to achieve cost reduction, as well as safety for fire prevention or electric shock.

The cover 42 is provided with the plate-shaped protrusions 42c and 42d, and the back cabinet body 41 is provided with the guide protrusion 41f, plate-shaped protrusions 41b and the aperture 41e along one long side of the opening part 41a. Therefore, when assembling the back cabinet 4, by inserting the plate-shaped protrusions 42c and 42d into the aperture 41e along the respective guide protrusion 41f and the protrusion 41b, alignment of the cover 42 with the back cabinet body 41 may be substantially completed.

The plate-shaped protrusions 42c and 42d are provided with the ribs 421c and 421d on the rear side of the television receiving apparatus 1. The rib 421c and 421d is disposed substantially parallel to the long side direction of the rectangular-shaped aperture 41e provided on the outer cylinder 41d or the long side direction of the opening part 41a.

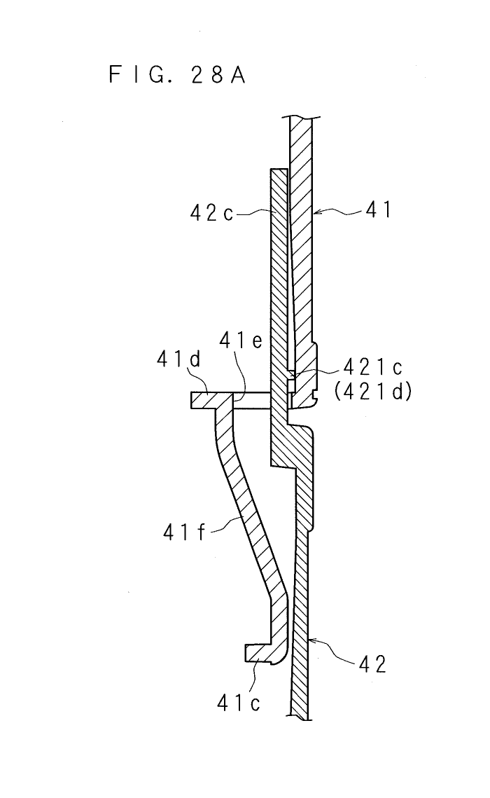

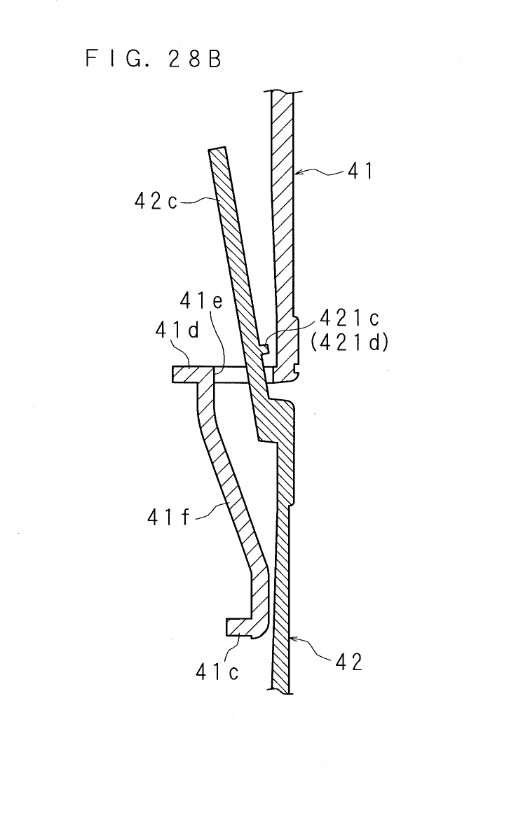

FIGS. 28A and 28B are cross-sectional views illustrating the plate-shaped protrusion 42c and the guide protrusion 41f assembled with the back cabinet 4. FIGS. 28A and 28B are cross-sectional views of the plate-shaped protrusion 42c and the guide protrusion 41f taken by cutting in a sectional plane parallel to the normal line of the cover 42 and the short side of the cover 42. FIG. 28A illustrates a normal state of the plate-shaped protrusion 42c and the guide protrusion 41f. FIG. 28B illustrates the plate-shaped protrusion 42c and the guide protrusion 41f with the plate-shaped protrusion 42c deformed so as to insert a foreign matter into the television receiving apparatus 1 from the aperture 41e.

Even when trying to insert the foreign matter such as clips, or the like from the aperture 41e, the rib 421c may prevent the insertion of the foreign matter. Even when the plate-shaped protrusion 42c is pressed to the front side of the television receiving apparatus 1, the rib 421c follows the plate-shaped protrusion 42c. Even when trying to insert a foreign matter into the television receiving apparatus 1 through the aperture 41e along the surface of the plate-like protrusion 42c, the rib 421c may prevent the insertion of the foreign matter. Similar to the rib 421c, the rib 421d also has a function to prevent the insertion of the foreign matter.

The outer cylinder 41d is a part of the enclosure of the back cabinet body 41, but it can be said that only the aperture 41e is also a passage connecting the television receiving apparatus 1 and the outside. Therefore, the ribs 421c and 421d also have a function as an enclosure.

In addition, after the back cabinet 4 is assembled, the back cabinet 4 may have a structure that, even when the plate-shaped protrusions 42c and 42d are pressed, it is rarely deformed. For example, when the plate-shaped protrusions 42c and 42d are inserted through the aperture 41e, a pawl for locking the tip portion of the plate-shaped protrusions 42c and 42d may be provided on the underside surface of the back cabinet body 41 (the front side of the television receiving apparatus 1).

When the locking claw 42e is locked to the peripheral wall end of the inner cylinder 41c forming the peripheral surface of the opening part 41a, the cover 42 may be easily fixed to the back cabinet body 41. If it is sufficient to fix the cover 42 only by the locking force of the locking claw 42e, the screw through holes 42a of the cover 42 and the bosses of the back cabinet body 41 may be omitted.

Alternatively, the cover 42 may be fixed to the back cabinet body 41 by the screws alone. In such a case, the locking claws 42e may be omitted.

Since the locking claws 42e are protrusion parts protruding from the cover 42, a risk of damage due to an excessive load may be considered. On the other hand, when the cover 42 is attached to the back cabinet body 41, it is necessary for the locking claw 42e to elastically deformation within limit range. Therefore, it is necessary to adjust the strength of the locking claws 42e. In this case, by changing the number or thickness of the reinforcing rib 423e, the shape or size of the rectangular-shaped slits 424e, or the thickness of the bent plate portion 421e, it is possible to adjust the strength of the locking claws 42e.

In order to increase the strength of the locking claws 42e, for example, when the thickness of the base of the bent plate portion 421e is increased, sink marks of material may occur in the corner forming the base of the bent plate portion 421e and the underside surface of the cover 42. However, even when the thickness of the base of the bent plate portion 421e is reduced to such an extent that the sink marks do not occur, by changing the attributes of the slits 424e or the 423e, it is possible to adjust the strength of the locking claw 42e.

The opening part 41a is provided in the upper center of the back cabinet body 41. However, the opening part 41a may be provided in other regions of the back cabinet body 41 in consideration of the position of the heating board. For example, instead of the inside of the back cabinet body 41, the opening part 41a may be a bored region including the end of the back cabinet body 41. In this case, the bored region is not an opening anymore, but rather becomes a cut out portion. Further, in accordance with the notch shape, the shape of the cover 42 may be determined.

The shape of the opening part 41a and the cover 42 is not limited to substantially rectangular, respectively. For example, in consideration of the position of the heating board, various shapes such as elliptical, circular, trapezoidal shapes, L-shapes, T-shapes, I-shapes, or irregular shapes may be selected as the shape of the opening part 41a and the cover 42.

### Embodiment 2

Hereinafter, other embodiments of the present invention will be described. Herein, the same parts as in the above-mentioned embodiment 1 will be denoted by the same reference numerals, a description thereof will be omitted, and only differences will be described.

Embodiment 2 is related to a configuration for eliminating deformation such as warping, deflection, ruffling, or the like of the back cabinet 4. Deformation of the back cabinet 4 may be a cause of vibration. Therefore, Embodiment 2 is also relates to the configuration for inhibiting the occurrence of the vibration which may provide a feeling of dissatisfaction to viewers.

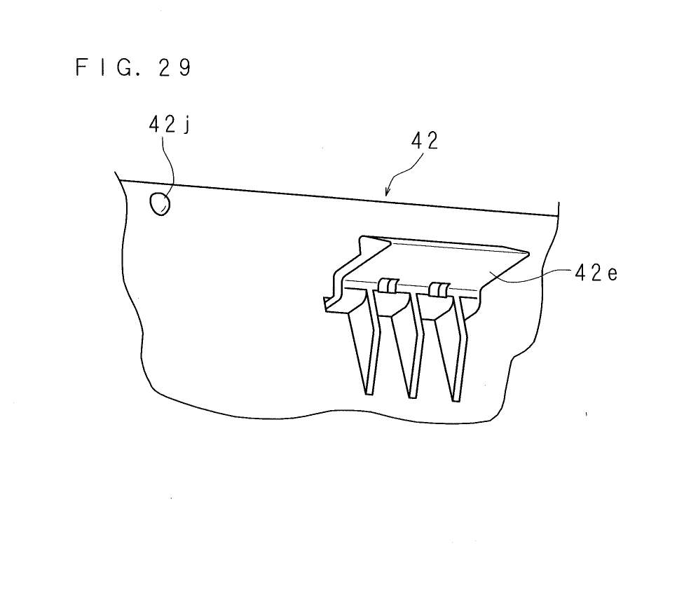

FIG. 29 is an enlarged perspective view illustrating the peripheral edge part of the underside surface of the cover 42. The peripheral edge part of the underside surface of the cover 42 is provided with the locking claw 42e and a hemispherical protrusion 42j. The hemispherical protrusion 42j is formed in a half sphere shape and is disposed on outer side of the locking claw 42e in the cover 42. In FIG. 29, the hemispherical protrusion 42j and the locking claw 42e are illustrated, respectively, but alternately, a plurality of the hemispherical protrusions 42j and locking claws 42e may be provided on the peripheral edge part of the cover 42 so as to surround the peripheral edge part of the underside surface of the cover 42 at substantially equal intervals.

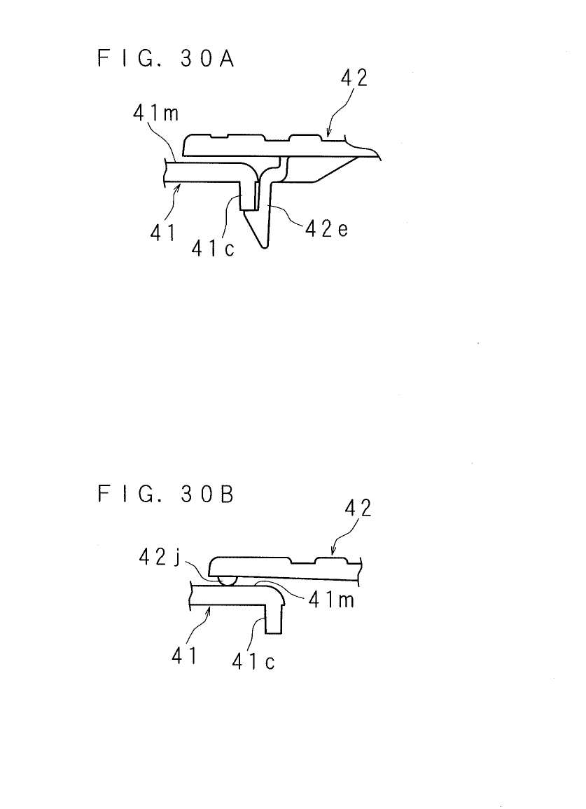

FIGS. 30A and 30B are cross-sectional views of the back cabinet body 41 and the cover 42 near the peripheral edge of the opening part 41a. FIGS. 30A and 30B are cross-sectional views of the assembled the back cabinet body 41 and the cover 42 taken by cutting in a sectional plane parallel to a normal line of the cover 42 and, for example, the short side of the cover 42. FIG. 30A illustrates a state in which the locking claw 42e is locked to the peripheral wall, that is, the peripheral wall edge face of the opening part 41a. The underside surface of the cover 42 near the base of the locking claw 42e is provided with a small gap from the back cabinet body 41. FIG. 30B illustrates a state that the hemispherical protrusion 42j provided on the peripheral edge part of the underside surface of the cover 42 abuts the upper side surface in the peripheral edge part of the opening part 41a between the inner cylinder 41c and the outer cylinder 41d. An underside surface of the back cabinet body 41 corresponding between the inner cylinder 41c and the outer cylinder 41d corresponds to the shelf 41m of the peripheral edge part of the opening part 41a (see FIG. 6). The radius of the hemispherical protrusion 42j is substantially identical to the distance of the gap between the underside surface of the cover 42 near the base of the locking claw 42e and the upper side surface of the back cabinet body 41.

The locking claw 42e is configured to control the deformation in a direction of a rising upward of the cover 42 with respect to the back cabinet body 41. The hemispherical protrusion 42j is configured to control the deformation in a direction of a sinking of the cover 42 with respect to the back cabinet body 41.

Since the cover 42 is an elongated large plate, deformation such as warping, deflection, ruffling, or the like may be easily occurred thereto. Further, when the thickness of the cover 42 is reduced, deformation tends to occur more significantly. In particular, at a portion where the cover 42 and the back cabinet body 41 is closed, the deformation of the cover 42 is easily-noticeable. However, the locking claws 42e and the hemispherical protrusion 42j arranged alternately may produce an effect of forcibly reducing the ruffling of the cover 42 to a low level, for example.

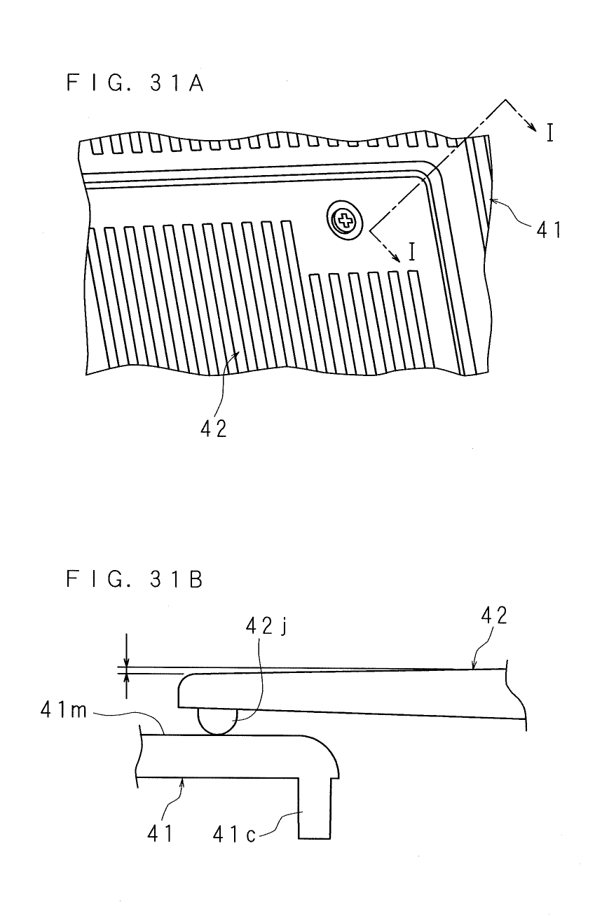

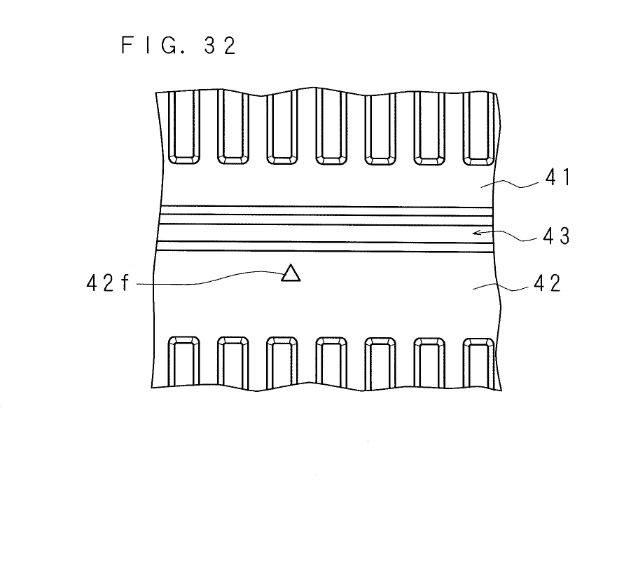

FIG. 31A is a partial enlarged view illustrating near a corner of the assembled cover 42. FIG. 31B is a cross-sectional view of the back cabinet body 41 and the cover 42 taken on a cutting line I-I of FIG. 31A. FIGS. 31A and 31B illustrate a deformation wherein the corner of the cover 42 has floated upward.

The corner of the cover 42 is a part wherein it is important to minimize the upward rising deformation. Therefore, as illustrated in FIG. 31B, the thickness in the corner of the cover 42 is formed so as to be slightly thinner toward the outside from the inside of the cover 42. In addition, the upper side surface in the corner of the cover 42 forms a gentle slope surface inclining from an upper side to the underside toward outside from the inside. Therefore, when the corner of the cover 42 is deformed by floating, the deformation amount of rising and a drop by a gradient of an upper side surface, that is preconfigured with an appropriate structure, compensate each other, thereby producing an effect that the deformation by rising becomes less obvious.

According to an alternating arrangement of the locking claw 42e and the hemispherical protrusion 42j, and the inclined structure of the upper side surface of the cover 42 corner, it is possible to reduce the deformation such as warping, deflection, ruffling of the cover 42 or the like. Therefore, it is also possible to inhibit the occurrence of vibration in the television receiving apparatus 1.

Embodiment 2 is as described above, and other than that is the same as embodiment 1, such that the corresponding parts have the same reference numbers, and a detailed description, operations and effects thereof will be omitted.

### Embodiment 3

Embodiment 3 is related to a configuration to inhibit change in a width of a groove 43 between the cover 42 and the back cabinet body 41 due to thermal expansion or contraction.

When the back cabinet body 41 and the cover 42 are made of molding materials having different flame retardancy from each other, thermal expansion coefficients of the back cabinet body 41 and the cover 42 may be different. In addition, since the shape of the back cabinet body 41 and the cover 42 is not a sphere or spherical shell of thermally isotropic material, they have anisotropy in terms of thermal deformation. Therefore, the relative positional relationship between the back cabinet body 41 and the cover 42 after assembling may be changed with a change in temperature.

FIG. 32 is an enlarged plan view illustrating an example of the back cabinet body 41 and the cover 42 after assembling as seen from a rear side of the television receiving apparatus 1. A groove 43 having a small width is formed between the outer edge (corresponding to a position of the outer cylinder 41d) of the shelf 41m in the peripheral edge part of the opening part 41a of the back cabinet body 41 and the periphery of the cover 42. As illustrated in FIG. 3, the groove 43 surrounds the entire periphery of the cover 42. The width of the groove 43 is constant at all parts of the periphery of the cover 42. The bottom of the groove 43 corresponds to the shelf 41m of peripheral edge of the opening part 41a. The groove 43 has a function to provide an appearance to the back cabinet 4, and to form a buffer for preventing contact due to thermal deformation between the peripheral surface (the inner peripheral surface of the inner cylinder 41c) of the opening part 41a of the back cabinet body 41 and the peripheral edge surface of the cover 42.

However, when the relative positional relationship between the back cabinet body 41 and the cover 42 is changed due to thermal deformation, the width of the groove 43 may be different depending on the position of the periphery of the cover 42. In this case, the result undermines the appearance of the television receiving apparatus 1.

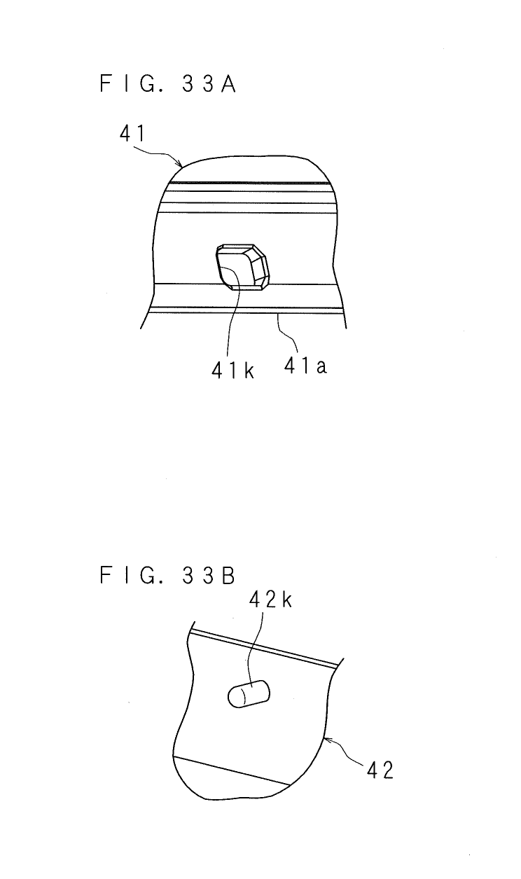

FIG. 33A is a perspective view illustrating a hole 41k formed in an upper edge part of the opening part 41a of the back cabinet body 41 as seen obliquely from the rear lower left of the television receiving apparatus 1. FIG. 33A illustrates an example of the hole 41k provided in the back cabinet body 41. FIG. 33B is a perspective view illustrating a columnar protrusion 42k provided on the peripheral edge part of the underside surface above the cover 42 as seen obliquely from the front upper right of the television receiving apparatus 1. FIG. 33B illustrates an example of the columnar protrusion 42k protruded from the cover 42.

The hole 41k is formed in, for example, a rectangular shape, and is formed in the shelf 41m of the peripheral edge of the opening part 41a. The hole 41k may have a circular shape, elliptical shape or the like. When seen from the underside of the back cabinet body 41, the hole 41k is disposed between the inner cylinder 41c and the outer cylinder 41d. A plurality of holes 41k may be formed along the periphery of the opening part 41a. The number of holes 41k disposed above and below the opening part 41a is twelve, for example, respectively. The number of holes 41k disposed on both lateral sides of the opening part 41a is five, for example, respectively.

The columnar protrusion 42k is formed in a column shape, and is erected on the underside of the cover 42. The tip of the columnar protrusion 42k is formed in a rounded hemispherical shape. The cross-sectional area of the columnar protrusion 42k taken by cutting in a sectional plane perpendicular to a height direction thereof is smaller than the opening area of the hole 41k. The columnar protrusion 42k is formed in the same number as the hole 41k on the peripheral edge part of the underside surface of the cover 42 along the periphery of the cover 42. The hole 41k is configured to be disposed in a position facing the hole 41k with the cover 42 attached to the back cabinet body 41. In addition, the columnar protrusion 42k is configured to loosely fit into the hole 41k arranged in the corresponding position with the cover 42 attached to the back cabinet body 41.

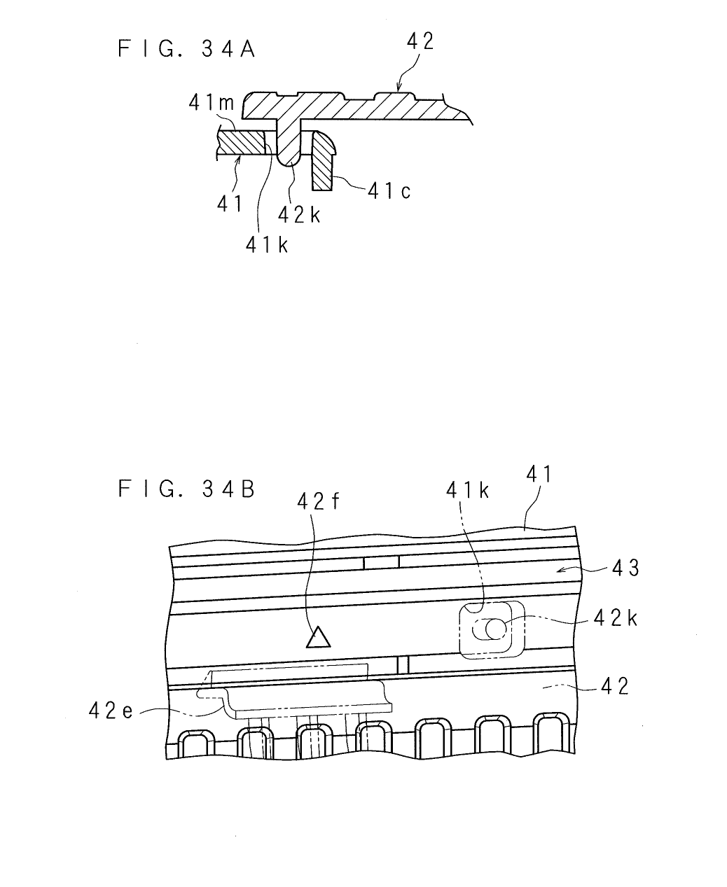

FIG. 34A is a cross-sectional view of an example of the hole 41k and the columnar protrusion 42k. FIG. 34A illustrates the assembled back cabinet body 41 and the cover 42 taken by cutting in a sectional plane parallel to the normal line of the cover 42 and, for example, the short side of the cover 42. FIG. 34A is an enlarged cross-sectional view illustrating a part of the hole 41k and the columnar protrusion 42k. FIG. 34B is a perspective view illustrating the assembled back cabinet body 41 and the cover 42 as seen from the upper side of the cover 42. In FIG. 34B, the hole 41k, the columnar protrusion 42k and the locking claw 42e originally hidden by the cover 42 is illustrated by a hidden double-dashed dotted line. FIG. 34B illustrates a state in which the columnar protrusion 42k is loosely fitted into the substantially center of the hole 41k. FIGS. 34A and 34B illustrate an example of the columnar protrusion 42k fitted in the hole 41k with the cover 42 attached to the back cabinet body 41.

When the relative position of the back cabinet body 41 and the cover 42 is changed due to a change in temperature after assembling, the position of the columnar protrusion 42k, which is loosely fitted into the hole 41k, moves relative to the peripheral surface of the hole 41k. However, when the columnar protrusion 42k abuts the peripheral surface of the hole 41k, the movement of the columnar protrusion 42k with respect to the hole 41k is controlled. Therefore, the relative movement of the cover 42 including the columnar protrusion 42k to the back cabinet body 41 including the hole 41k is controlled. Since the plurality of the columnar protrusion 42k and the hole 41k are provided in the peripheral edge of the cover 42, the control level and orientation for the movement of the columnar protrusion 42k with respect to hole 41k vary depending on the location of the periphery of the cover 42. As a result, since a change in the width of the groove 43 between the back cabinet body 41 and the cover 42 is regulated at each position of the periphery of the cover 42, the width of the groove 43 in the portion with the periphery of the cover 42 may be constantly maintained. Therefore, the hole 41k and the columnar protrusion 42k contribute to maintain the aesthetic appearance of the back cabinet 4.

Embodiment 3 is as described above, and other than that is the same as embodiments 1 and 2, such that the corresponding parts have the same reference numbers, and a detailed description, operations and effects thereof will be omitted.

### Embodiment 4

Embodiment 4 is related to a configuration in which the back cabinet 4 is provided with a plurality of lattice opening parts, rather than cutting out the back cabinet 4 to form the single opening part 41a therein. Further, embodiment 4 is related to a configuration in which a thin punching sheet with a plurality of bored holes is adhered to grids forming the plurality of opening parts, instead of the cover 42 covering the opening part in embodiments 1 to 3.

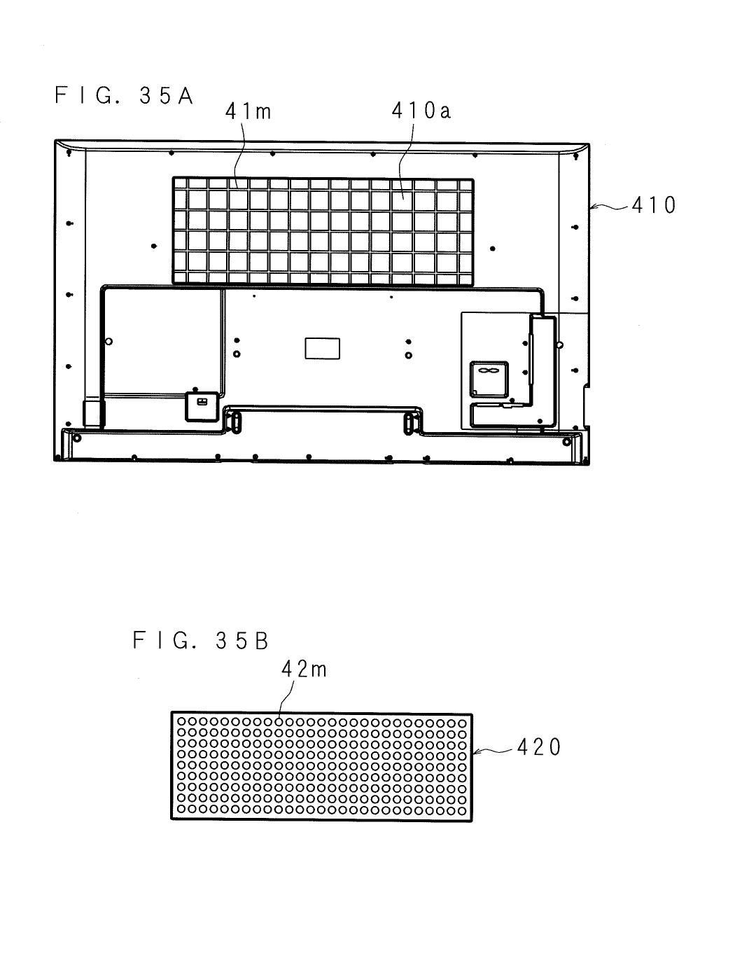

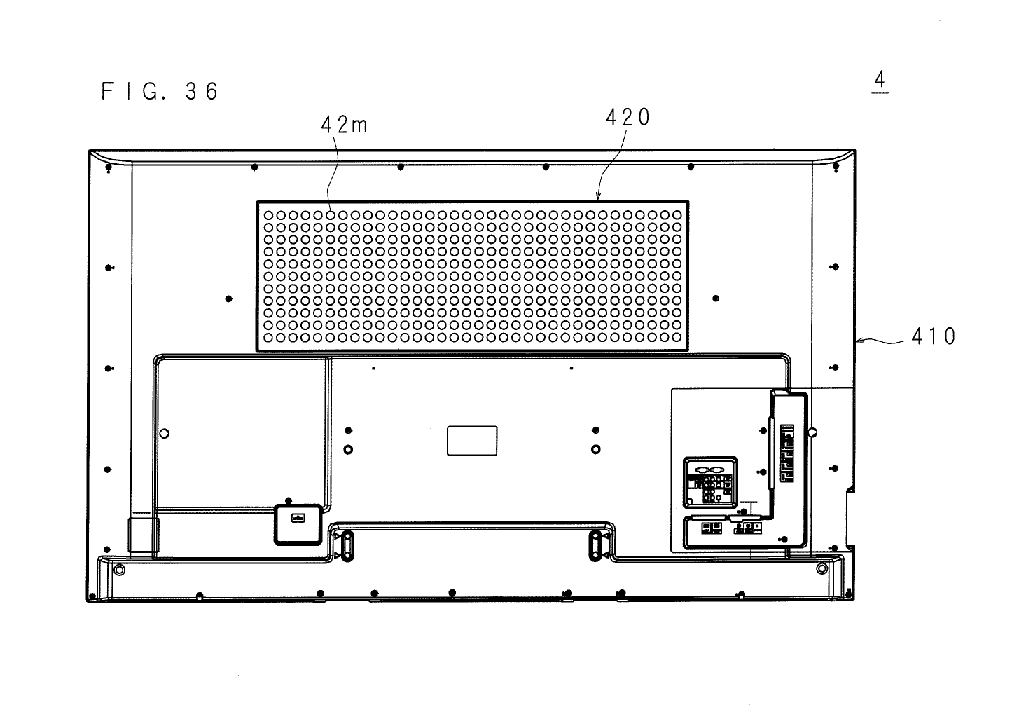

FIG. 35A is a plan view illustrating the back cabinet body 410 as seen from the rear side of the television receiving apparatus 1. FIG. 35B is a plan view illustrating a cover sheet 420 as seen from the rear side of the television receiving apparatus 1. FIGS. 35A and 35B illustrate an example of a dividing member of the back cabinet 4 as seen from the rear side of the television receiving apparatus 1, respectively. The back cabinet 4 includes a back cabinet body 410 and the cover sheet 420.

The back cabinet body 410 has an inner cylinder 41c and an outer cylinder 41d similar to those of the back cabinet body 41 (for simplicity, the inner cylinder 41c and the outer cylinder 41d are not illustrated in FIG. 35A, therefore, see the inner cylinder 41c and the outer cylinder 41d illustrated in FIGS. 4 and 6). On the other hand, the back cabinet body 410 has no plate-shaped protrusion 41b, guide protrusion 41f and the like. The inner cylinder 41c and the outer cylinder 41d serve as providing the enclosure.

The back cabinet body 410 has a plurality of grids 41m arranged in a vertical direction and horizontal direction at a portion corresponding to the opening part 41a of the back cabinet body 41. By the grids 41m formed in a lattice structure, a plurality of the opening parts 410a are formed in the upper center of the back cabinet body 410. The thickness and the number of the grids 41m may be determined in consideration of the strength of the back cabinet body 410. FIG. 35A illustrates an example of the grids 41m having a prescribed thickness and number.

The back cabinet body 410 including the inner cylinder 41c, the outer cylinder 41d and the grids 41m is formed by integral molding using a material (for example, a resin material) having a flame-retardancy rating of V-1 or more.

The cover sheet 420 is a thin lightweight sheet formed by using a material (for example, a resin material) having a flame-retardancy rating of HB. The shape and planar size of the cover sheet 420 is determined according to the whole of the plurality of opening parts 410a. In the example of FIG. 35B, the cover sheet 420 has a rectangular shape. The thickness of the cover sheet 420 is 0.5 mm, for example. The cover sheet 420 has a plurality of holes 42m formed by punching. The size of each hole 42m may be a size to sufficiently meet safety standards for shielding foreign matter. The shape of the hole 42m is not particularly limited and, for example, may be a circular hole having a diameter of 2 mm to 4 mm.

The cover sheet 420 has no locking claw 42e, plate-shaped protrusions 42c and 42d, and the like included in the cover 42.

FIG. 36 is a plan view illustrating an example of the back cabinet 4 as seen from the rear side of the television receiving apparatus 1. When assembling the back cabinet 4, the cover sheet 420 is adhered to the grids 41m of the back cabinet body 410 by an adhesive, double-sided tape or the like.

According to the television receiving apparatus 1 of embodiment 4, since the back cabinet body 410 is provided with the plurality of opening parts 410a, it is possible to reduce the pressure in a mold during molding.

The cover sheet 420 is lightweight, and during the assembling work of the television receiving apparatus 1, the cover sheet 420 is easily adhered to the grids 41m. Therefore, the burden on workers may be reduced, and efficiency of assembly is improved.

Since the inner cylinder 41c and the outer cylinder 41d having a function of providing the enclosure are formed around the grid part of the back cabinet body 410 toward the inside of the television receiving apparatus 1, it is possible to lower the flame retardancy rating of the cover sheet 420. Further, the outer cylinder 41d may be omitted.

The opening part 410a formed in the back cabinet body 410 and the hole 42m formed in the cover sheet 420 may effectively release heat generated in the television receiving apparatus 1 to the outside.

Embodiment 4 is as described above, and other than that is the same as embodiments 1 to 3, such that the corresponding parts have the same reference numbers, and a detailed description, operations and effects thereof will be omitted.

### Embodiment 5

Embodiment 5 is related to a configuration of a linearly divided back cabinet 4 into two upper and lower casing parts. The lower rear surface of the display unit 2 provided with heating elements such as a power board P, drive board D, and the like is covered by a lower back cabinet having a high flame retardancy. The rear upper portion of the display unit 2 with no heating element is covered by an upper back cabinet having a low flame retardancy.

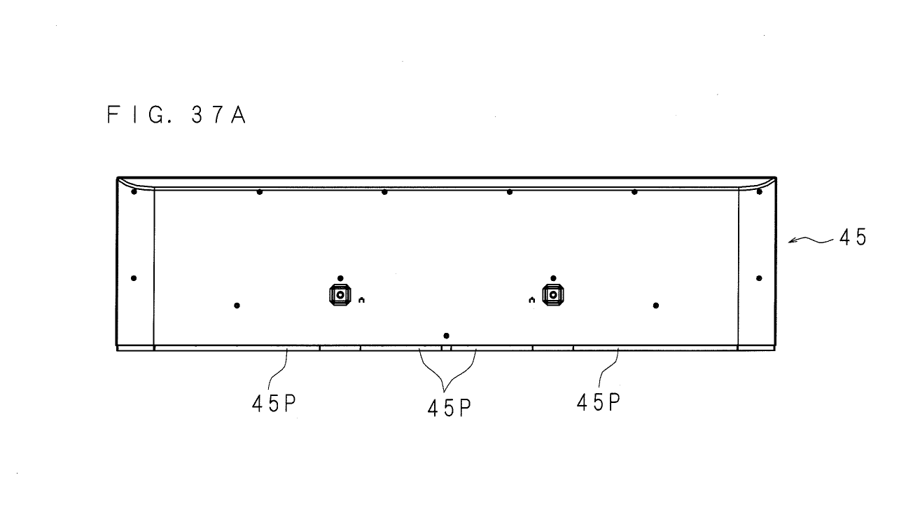

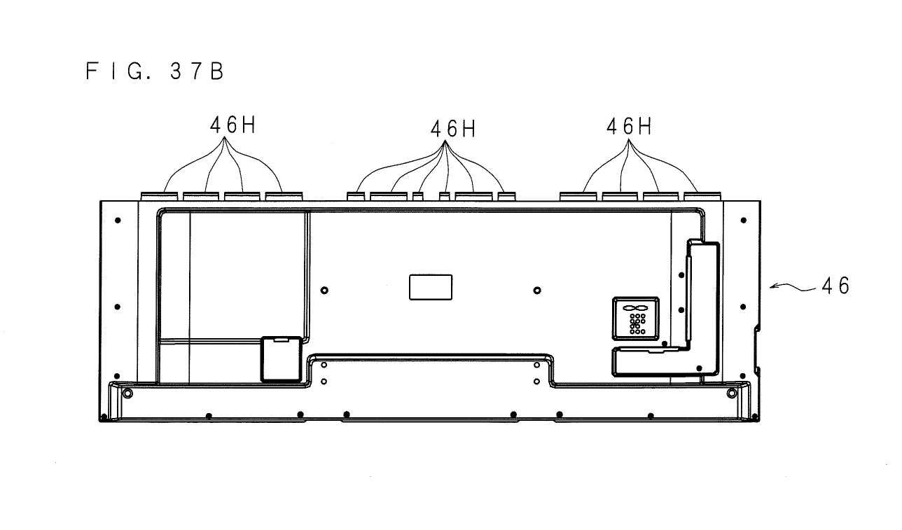

The back cabinet 4 includes an upper back cabinet 45 and a lower back cabinet 46. FIG. 37A is a plan view illustrating the upper back cabinet 45 as seen from the rear side of the television receiving apparatus 1. FIG. 37B is a plan view illustrating the lower back cabinet 46 as seen from the rear side of the television receiving apparatus 1. FIGS. 37A and 37B illustrate an example of the divided members of back cabinet 4 as seen from the rear side of the television receiving apparatus 1.

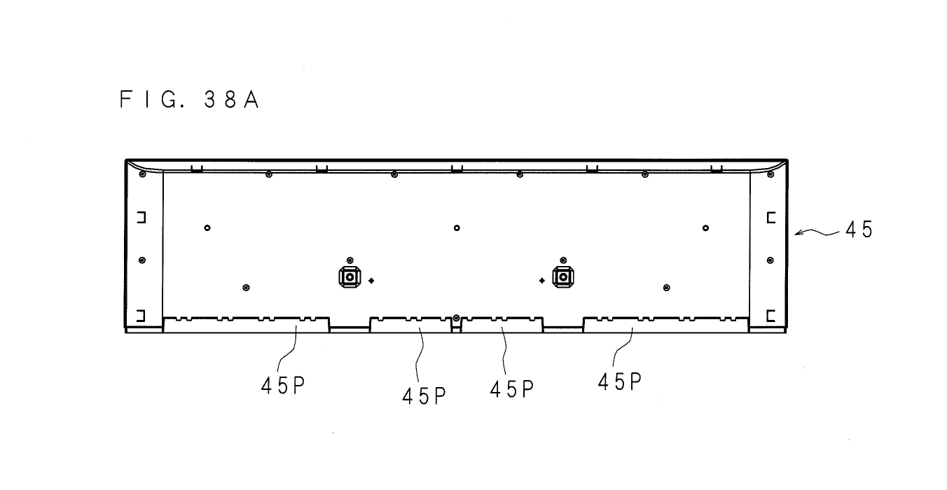

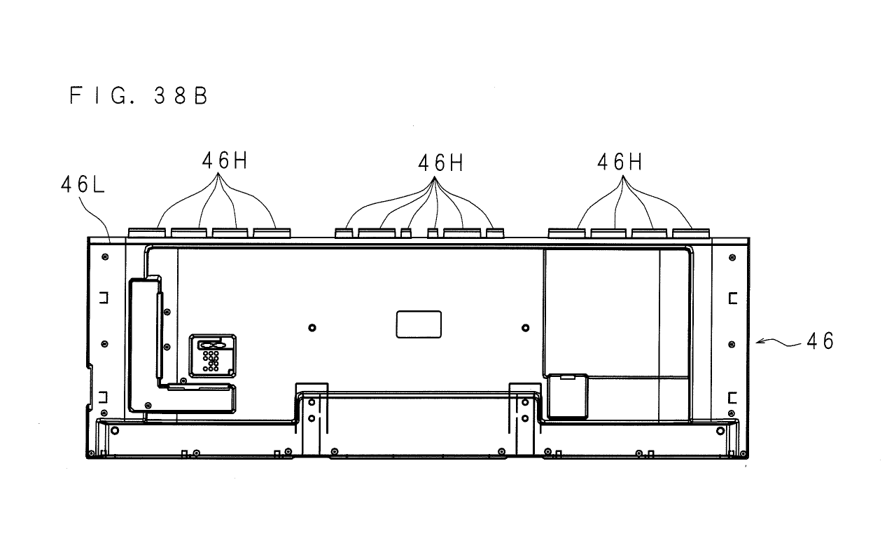

FIG. 38A is a plan view illustrating the upper back cabinet 45 as seen from the front side of the television receiving apparatus 1. FIG. 38B is a plan view illustrating the lower back cabinet 46 as seen from the front side of the television receiving apparatus 1. FIGS. 38A and 38B illustrate an example of the divided members of the back cabinet 4 as seen from the front side of the television receiving apparatus 1.

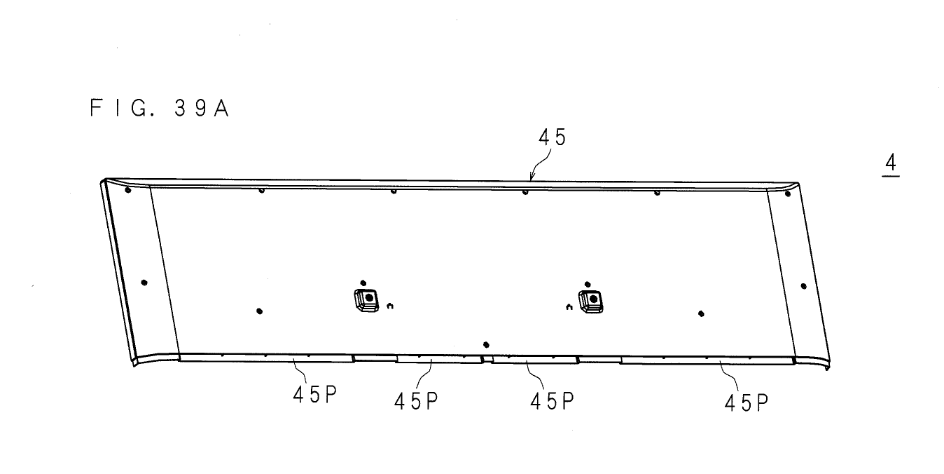

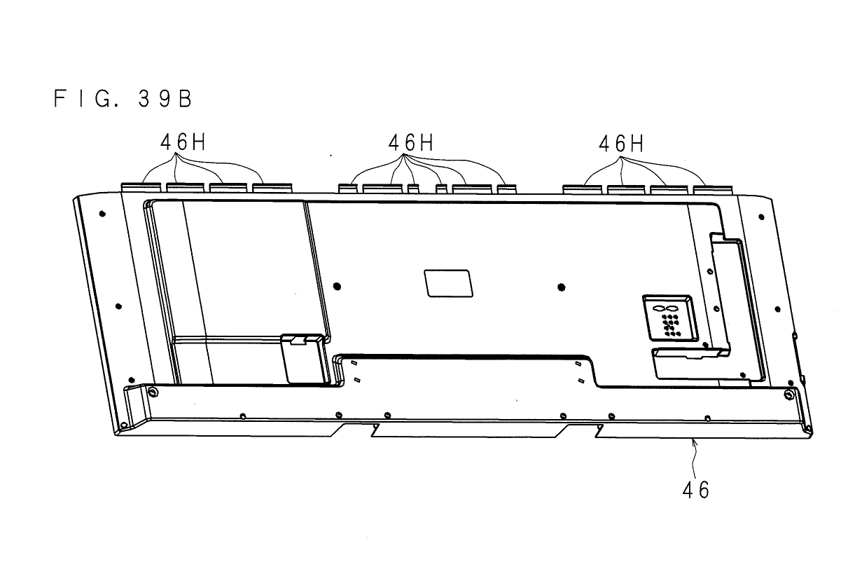

FIG. 39A is a perspective view illustrating the upper back cabinet 45 as seen obliquely from the rear lower left of the television receiving apparatus 1. FIG. 39B is a perspective view illustrating the lower back cabinet 46 as seen obliquely from the rear lower left of the television receiving apparatus 1. FIGS. 39A and 39B illustrate an example of the divided members of the back cabinet 4 as seen obliquely from the rear lower left of the television receiving apparatus 1.

The back cabinet 4 according to embodiment 5 is largely divided into the upper back cabinet 45 and the lower back cabinet 46 by a linear dividing line passing the center in a horizontal direction. Both of the upper back cabinet 45 and the lower back cabinet 46 have a laterally long and substantially rectangular shape as seen from the upper side (the rear side of the television receiving apparatus 1) plan view and the underside (the front side of the television receiving apparatus 1) plan view.

The upper back cabinet 45 is the casing part covering the upper rear surface of the display unit 2 with no heating element, and is formed by integral molding using a material (for example, a resin material) having a flame retardancy rating of HB. On the other hand, the lower back cabinet 46 is the casing part covering the power board P, drive board D, and the like, which generate heat as a voltage is applied thereto, and is formed by integral molding using a material (for example, a resin material) having a flame retardancy rating of V-1 or more. The lower back cabinet 46 includes a rib 46L which is provided in a portion close to the underside (the front side of the television receiving apparatus 1) upper end thereof and elongates in the horizontal direction to serve as the enclosure part (see FIG. 38B). The rib 46L will be described in detail below.

The upper back cabinet 45 includes pockets 45P formed at lower edge thereof. Mouths of the pockets 45P are oriented downward, and the depth direction of the pockets 45P is upward. The pockets 45P are formed in a horizontally elongating shape, and the horizontal width of the pockets 45P is longer than the length thereof in the depth direction. The upper back cabinet 45 is provided with four pockets 45P, for example. Each of the pockets 45P arranged in the horizontal direction is separated at an interval in the horizontal direction along the lower edge of the upper back cabinet 45. All of the four pockets 45P have the same length in the depth direction.

The pockets 45P which are respectively disposed on left and right ends have the same lateral width as each other as seen from the front. Further, the pockets 45P which are sandwiched between the pockets 45P arranged on left and right ends and disposed in both sides of the lower edge center of the upper back cabinet 45 also have the same lateral width as each other as seen from the front. Meanwhile, the lateral width of the pockets 45P arranged on left and right ends is larger than the width of the pockets 45P arranged on central both sides. The displacement and size distribution of each of the pockets 45P is bilaterally symmetrical with respect to the lower edge center of the upper back cabinet 45.

Hooks 46H are formed on the upper edge of the lower back cabinet 46 elongating upwardly. In addition, a plurality of the hooks 46H are separately arranged in a horizontal direction at intervals. In the example of the lower back cabinet 46 in FIGS. 37B, 38B and 39B, fourteen hooks 46H are formed on an upper edge of the lower back cabinet 46. All of these fourteen hooks 46H have the same length in the vertical direction. Four hooks 46H are respectively provided in a position of the lower back cabinet 46 facing the pockets 45P respectively arranged on left and right ends of the lower edge of the upper back cabinet 45. Three hooks 46H are respectively provided in a position of the lower back cabinet 46 facing the two pockets 45P arranged on both sides of the lower edge center of the upper back cabinet 45.

The lateral width of the hooks 46H are different from each other. The four hooks 46H disposed on the position of the lower back cabinet 46 facing the pockets 45P respectively arranged on left and right ends of the lower edge of the upper back cabinet 45 have the longest lateral width, and each width thereof is the same. Each of the three hooks 46H respectively provided in the position of the lower back cabinet 46 facing the two pockets 45P arranged on both sides of the lower edge center of the upper back cabinet 45 has a different lateral width. Among these three hooks 46H, each hook 46H disposed in the center thereof has the longest lateral width, and each hook 46H close to the upper edge center of the lower back cabinet 46 has the shortest lateral width. The displacement and size distribution of the fourteen hooks 46H is bilaterally symmetrical with respect to the lower edge center of the lower back cabinet 46.

The hook 46H is configured to be inserted into the pocket 45P. By this configuration, when the hook 46H is locked into the pocket 45P, the upper back cabinet 45 and the lower back cabinet 46 are combined with each other.

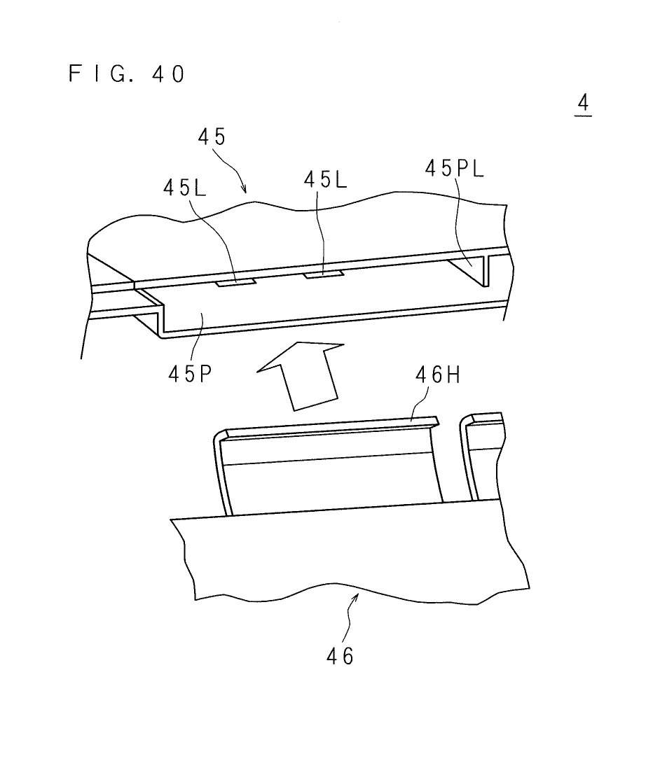

FIG. 40 is a view for explaining a state during assembling the back cabinet 4. FIG. 40 illustrates a portion of the upper back cabinet 45 and the lower back cabinet 46. In addition, a white arrow in FIG. 40 illustrates the insertion direction of the hook 46H to the pocket 45P. The plurality of hooks 46H are inserted in one pocket 45P. In this regard, the pocket 45P has a pocket partition rib 45PL formed to partition the inside thereof corresponding to separating the hooks 46H. The pocket partition rib 45PL is provided on an inner surface of the pocket 45P facing the front side of the television receiving apparatus 1.

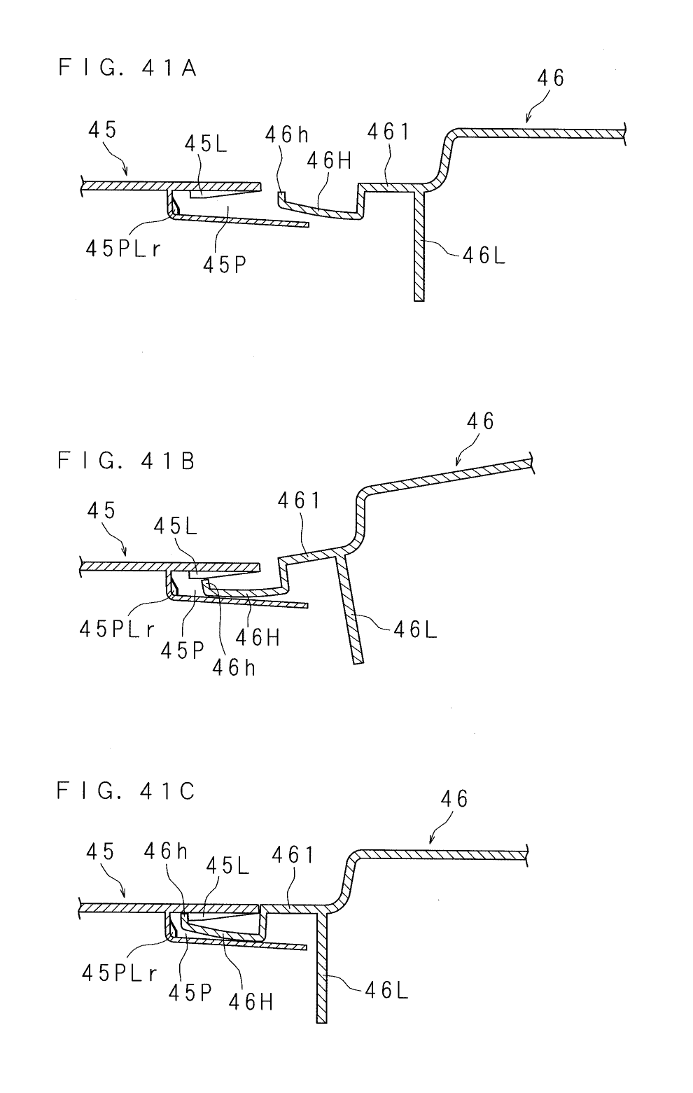

FIGS. 41A to 41C are cross-sectional views for explaining a state during assembling of the back cabinet 4. FIGS. 41A to 41C illustrate a portion of the upper back cabinet 45 and the lower back cabinet 46, respectively. In FIGS. 41A to 41C, the bottom and top are the upper side and underside of the back cabinet 4, respectively. In addition, in FIGS. 41A to 41C, the bottom and top direction are the front and rear sides of the television receiving apparatus 1, respectively. Further, in FIGS. 41A to 41C, the left and right direction are the top and bottom side of the television receiving apparatus 1, respectively. FIGS. 41A to 41C illustrate a cross-section taken by cutting the upper back cabinet 45 and the lower back cabinet 46 in a surface perpendicular to the horizontal direction, respectively.

FIG. 41A illustrates the state before inserting the hook 46H of the lower back cabinet 46 into the pocket 45P of the upper back cabinet 45. FIG. 41B illustrates a state during inserting the hook 46H of the lower back cabinet 46 into the pocket 45P of the upper back cabinet 45. FIG. 41C illustrates a state in which the hook 46H of the lower back cabinet 46 is locked to the pocket 45P of the upper back cabinet 45.

The upper end of the lower back cabinet 46 has a step portion 461 which is bent and stepped to the underside (the front side of the television receiving apparatus 1) of the back cabinet 4. The hooks 46H are provided at the tip of the step portion 461. The hook 46H is bent from the tip of the step portion 461, and is further sunk to the underside (the front side of the television receiving apparatus 1). Therefore, the step portion 461 and the hook 46H are formed in a crank shape having two stepped bent portions. A nose 46h bent to the upper side (the rear side of the television receiving apparatus 1) of the back cabinet 4 is provided at the tip of the hook 46H.

On the other hand, the pocket 45P has a hook locking rib 45L on the inner surface thereof facing the front side of the television receiving apparatus 1 to be locked to the nose 46h of the hook 46H. The height of the hook locking rib 45L increases toward the depth from mouth of the pocket 45P, and is cut off at the front from the innermost surface of the pocket 45P. The hook locking rib 45L is formed in a triangular prism shape, and in FIGS. 41A to 41C, the hook locking rib 45L is seem as a wedge shape. Each hook 46H is locked two hook locking ribs 45L provided on the inner surface of the pocket 45P (see FIG. 40). Each hook locking rib 45L is arranged in the horizontal direction, so as to correspond to all of the fourteen hooks 46H.

When the nose 46h of the hook 46H is locked to the hook locking rib 45L, the lower back cabinet 46 is inclined to the upper back cabinet 45, such that the lower end side of the lower back cabinet 46 is positioned more toward the upper side (the rear side of the television receiving apparatus 1) (see FIG. 41B). Then, the hook 46H is inserted into the pocket 45P so as to cover the hook locking rib 45L with the hook 46H. In order to release the inclination of the lower back cabinet 46 to the upper back cabinet 45, the lower back cabinet 46 is pivoted around the nose 46h, and thereby the lower end side of the lower back cabinet 46 more closely approximates to the underside (the front side of the television receiving apparatus 1). When the hook 46H is locked to the hook locking rib 45L (see FIG. 41C), the lower surface of the nose 46h abuts the upper surface of the hook locking rib 45L, and the underside (the front side of the television receiving apparatus 1) surface of the hook 46H abuts the inner surface of the pocket 45P. Further, when the hook 46H is locked to the hook locking rib 45L (see FIG. 41C), the lower end face of the upper back cabinet 45 abuts the apical face of the end portion 461.

When the lower back cabinet 46 is separated from the upper back cabinet 45, the lower back cabinet 46 is removed from the upper back cabinet 45, by the procedure reverse to the order in FIGS. 41A, FIGS. 41B and 41C.

When the upper back cabinet 45 is combined with the lower back cabinet 46, it is preferable that the upper side (the rear side of the television receiving apparatus 1) surface of the step portion 461 and the upper side (the rear side of the television receiving apparatus 1) surface of the upper back cabinet 45 form a smooth plane. For this, the step of the bent portion at the base of the hook 46H may be adjusted. Therefore, appearance of the rear surface of the television receiving apparatus 1 may be maintained.

Further, a pocket reinforcing rib 45PLr for reinforcing the strength of the pocket 45P is provided in the corner forming the innermost surfaces of the pocket 45P and the inner front side surface of the pocket 45P.

The rib 46L is protruded from the underside surface (the front side of the television receiving apparatus 1) at the root portion of the step portion 461. The rib 46L serves as an enclosure for isolating the upper back cabinet 45 from the power board P, drive board D, and the like covered with the lower back cabinet 46.

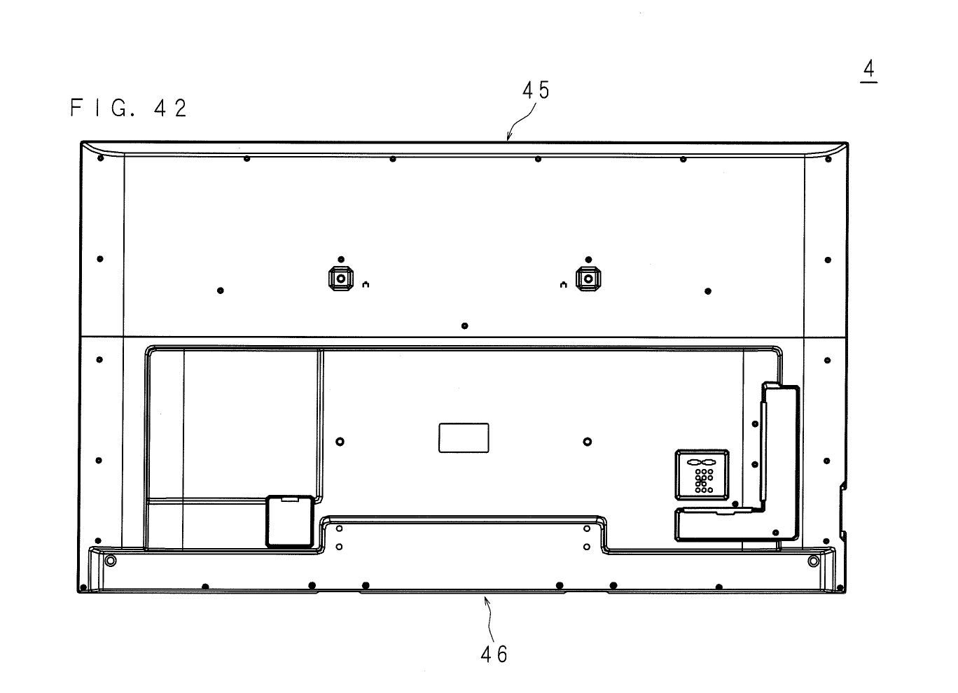

FIG. 42 is a plan view illustrating an example of the back cabinet 4 as seen from the rear side of the television receiving apparatus 1.

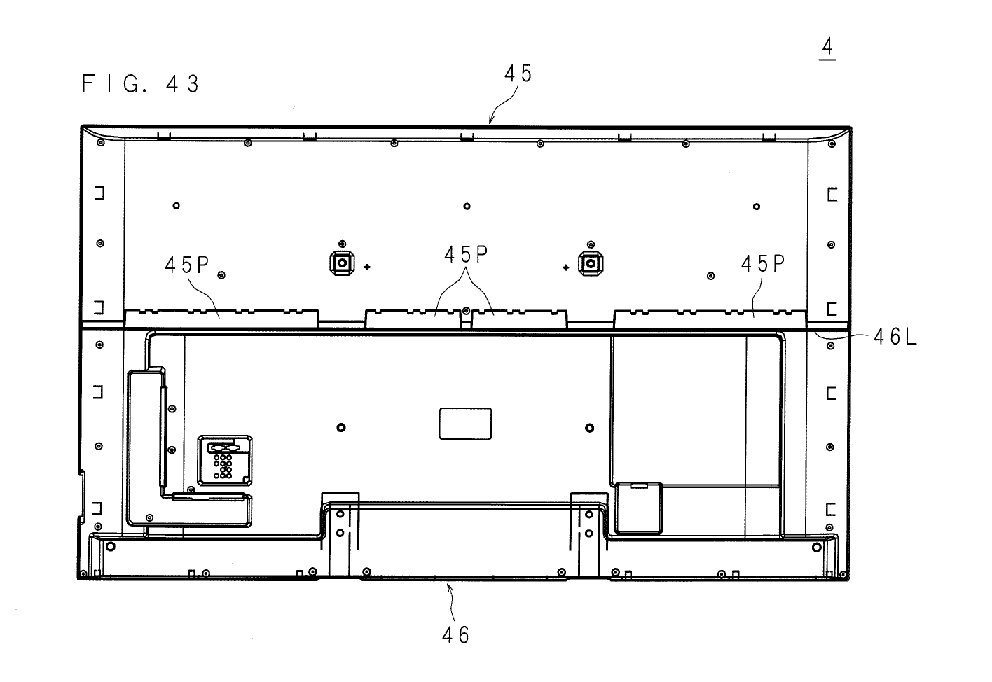

FIG. 43 is a plan view illustrating the example of the back cabinet 4 as seen from the front side of the television receiving apparatus 1.

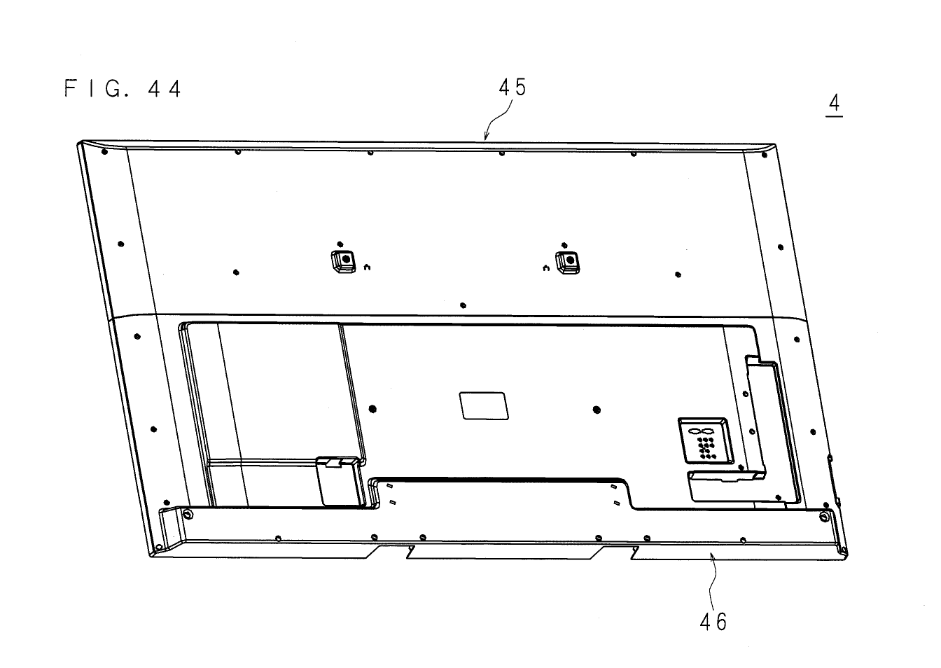

FIG. 44 is a perspective view illustrating an example of the back cabinet 4 as seen obliquely from the rear lower left of the television receiving apparatus 1.

After assembling the back cabinet 4, the hook 46H is housed in the pocket 45P, thereby it is not possible to see the hook 46H from the outside or inside of the television receiving apparatus 1 (FIGS. 42 to 44). In addition, it is also not possible to see the pocket 45P from the standpoint of appearance (FIG. 42 and FIG. 44).

Further, it is also not possible to see the pocket rib 46L from the standpoint of appearance (FIG. 42 and FIG. 44). However, when the back cabinet 4 is seen from the inside of the television receiving apparatus 1 (FIG. 43), the rib 46L is a partition wall that partitions, in a straight line, the upper back cabinet 45 and the lower back cabinet 46.

Next, a method of attaching the back cabinet 4 to the front cabinet 3 and the display unit 2 will be described. The front cabinet 3, the display unit 2 and the upper back cabinet 45 are aligned and superposed on the horizontal plane in this order. Then, screws are inserted into the screw through holes formed in the peripheral edge of the upper back cabinet 45, and these members are fixed to each other by screwing.

Next, the hook 46H is inserted into the pocket 45P, and the lower back cabinet 46 is temporarily fixed to the upper back cabinet 45 by the procedure shown in FIGS. 41B and 41C. Thereafter, screws are inserted into the screw through holes formed in the peripheral edge of the lower back cabinet 46, and the lower back cabinet 46 is fixed to the front cabinet 3 and the display unit 2 by screwing.

Further, when repairing or replacing the receiving unit T, power board P, or drive board D covered with the lower back cabinet 46, only the lower back cabinet 46 is removed, while the upper back cabinet 45 is fixed.

According to the television receiving apparatus 1 of embodiment 5, since the back cabinet 4 is divided into the upper back cabinet 45 and the lower back cabinet 46, it is possible to reduce the pressure in a mold during molding.

The upper back cabinet 45 and the lower back cabinet 46 have a combining structure (the pocket 45P and the hook 46H) capable of easily assembling and disassembling, respectively. Therefore, even when the number of parts of the back cabinet 4 is increased to two, it does not significantly affect the work required for the assembling and disassembling of the back cabinet 4.

Since the lower back cabinet 46 having the rib 46L is formed as the single body enclosure, even when the flame retardancy rating of the upper back cabinet 45 is lowered, it does not affect the product compliance in terms of safety standards.

According to the television receiving apparatus 1 of embodiment 5, since it is possible to remove only the lower back cabinet 46, maintenance work for the receiving unit T, power board P, or drive board D can be easily performed.

Embodiment 5 is as described above, and other than that is the same as embodiments 1 to 4, such that the corresponding parts have the same reference numbers, and a detailed description, operations and effects thereof will be omitted.

### Embodiment 6

Embodiment 6 is related to a configuration of two-color molding (double molding) the back cabinet 4 including the back cabinet body 41 and the cover 42. Therefore, the back cabinet 4 is molded in one body without dividing it into the back cabinet body 41 and the cover 42. A region corresponding the back cabinet body 41 is made of a high flame retardancy resin material (for example, a rating of V-1 or more), and a region corresponding to the cover 42 is made of a low flame retardancy resin material (for example, a rating of HB).

Since the back cabinet 4 according to embodiment 6 is molded in one body, when assembling the television receiving apparatus 1, it is not necessary to combine the region corresponding to the back cabinet body 41 and the cover 42. Therefore, the back cabinet 4 according to embodiment 6, has no plate-shaped protrusion 41b, guide protrusion 41f as well as locking claw 42e, plate-shaped protrusions 42c and 42d, and the like, which are included in the back cabinet body 41 and the cover 42, respectively.

### Embodiment 6-1

Embodiment 6-1 is related to a configuration in which partitions are provided between cavities inside of the molds respectively corresponding to the back cabinet body 41 and the cover 42 to mold the back cabinet 4.

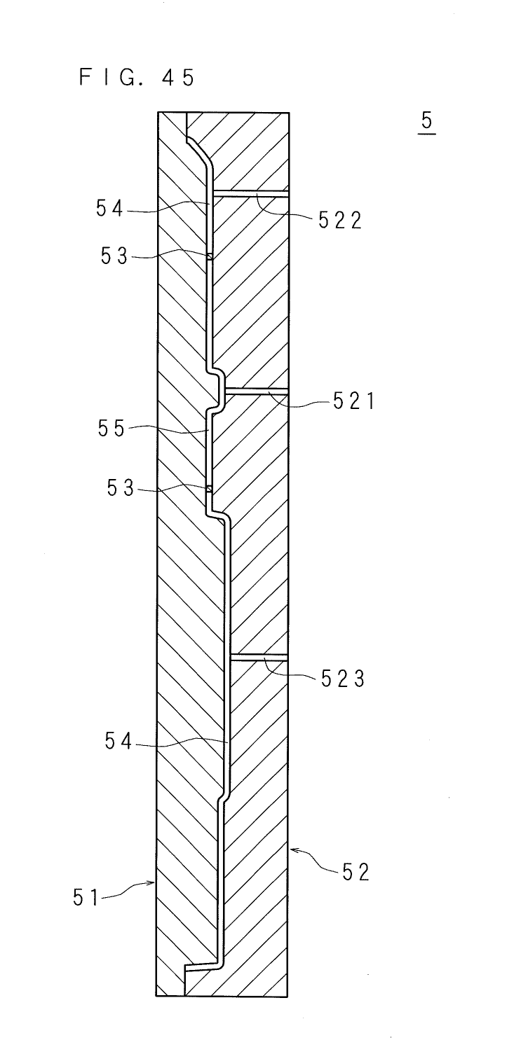

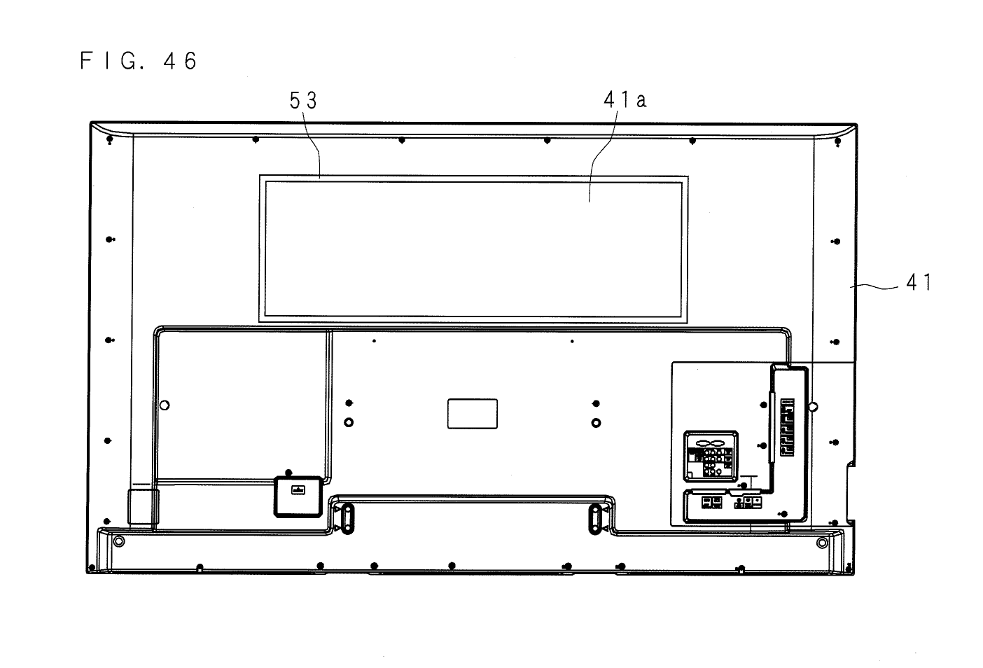

FIG. 45 is a cross-sectional view illustrating an example of a mold 5 for molding the back cabinet 4. The top and bottom direction in FIG. 45 correspond to the top and bottom side of the back cabinet 4, respectively. The right and left directions in FIG. 45 correspond to the upper side and underside of the back cabinet 4, respectively. FIG. 45 is a cross-sectional view of the mold 5 taken by cutting in a sectional plane parallel to a vertical direction and the normal line of the back cabinet 4.

The mold 5 includes a male mold 51, a female mold 52 and a partition part 53. The male mold 51 is a movable core, and the female mold 52 is a fixed cavity. The female mold 52 has runners 521, 522 and 523 which are flow passages for a resin material to be filled in cavities 54 and 55 inside the mold 5. The runner 521 is a flow passage for forming a region corresponding to the cover 42. The runners 522 and 523 are flow passages for forming a region corresponding to the back cabinet body 41. The mold 5 is closed (clamped) and open by sliding the male mold 51, for example.

FIG. 46 is a view for explaining a state in which the partition part 53 is overlapped with the back cabinet body 41.

FIG. 46 illustrates the back cabinet body 41 and the partition part 53 as seen from the rear side of the television receiving apparatus 1. The partition part 53 is a frame-shaped member disposed in a portion of the female mold 52 corresponding to the periphery of the opening part 41a of the back cabinet body 41. The partition part 53 has a function of blocking the resin material so as not to flow into the cavity 54, corresponding to the back cabinet body 41, when the resin material is injected into the cavity 55, corresponding to the cover 42, in the mold. The width of the frame of the partition part 53 as seen from the front side is identical to the width of the groove 43, for example. The groove 43 is a space formed between the outer edge of the shelf 41m in the peripheral edge part of the opening part 41a and the periphery of the cover 42 (see FIGS. 3, 32 and 34B).

Next, a method of molding the back cabinet 4 according to embodiment 6-1 will be described. First, the female mold 52 is mounted in the partition part 53, and the mold 5 is closed by sliding the male mold 51. Then, a low flame retardancy resin material is injected into the cavity 55 corresponding to the cover 42 from a nozzle through the runner 521. After the low flame retardancy resin material forming the cover 42 (for example, after 2 or three minutes passes from the ending of the injection) is cooled, the mold 5 is opened, and then the partition part 53 is taken out from the female mold 52. Thereafter, the mold 5 is closed again. Next, a high flame retardancy resin material is injected into the cavity 54 corresponding to the back cabinet body 41 from the nozzle through the runners 522 and 523. In a step that the high flame retardancy resin material forming the back cabinet body 41 has been cooled, the mold 5 is opened, and then the molded part of the back cabinet 4 is taken out from the mold 5.

The inner cylinder 41c and the outer cylinder 41d made of a high flame retardancy resin are formed around the region corresponding to the cover 42 in the underside surface (the front side of the television receiving apparatus 1) of the back cabinet 4 formed by the mold 5. The inner cylinder 41c and the outer cylinder 41d provide a function of the enclosure.

Further, it is possible to elongate the partition part 53 in a direction of the male mold 51 in FIG. 45, without providing the inner cylinder 41c and the outer cylinder 41d. After taking out the partition part 53 and closing the mold 5, the injected high flame retardancy resin material fills the cavity 54 occupied by the partition part 53. By increasing the height of the partition part 53 toward the front side of the television receiving apparatus 1, the high flame retardancy resin material filled in the cavity 54 occupied by the partition part 53 forms a side providing a function of the enclosure.

In embodiment 6-1, the region corresponding to the cover 42 is molded, and then the region corresponding to the back cabinet body 41 is molded. However, these parts may be molded in reverse order. That is, the region corresponding to the back cabinet body 41 may be molded, and then the region corresponding to the cover 42 may be molded.

In embodiment 6-1, the processes of mounting and taking out the partition part 53 are included in the cycle for forming the back cabinet 4, but it is possible to mold the back cabinet 4 in one cycle from the process of closing the mold to the process of taking out the molded part through the mold opening stroke.

### Embodiment 6-2

Embodiment 6-2 is related to a configuration that, after the region corresponding to the cover 42 is molded in advance, the molded cover 42 is mounted in the female mold 52, and then the region corresponding to the back cabinet body 41 is molded.

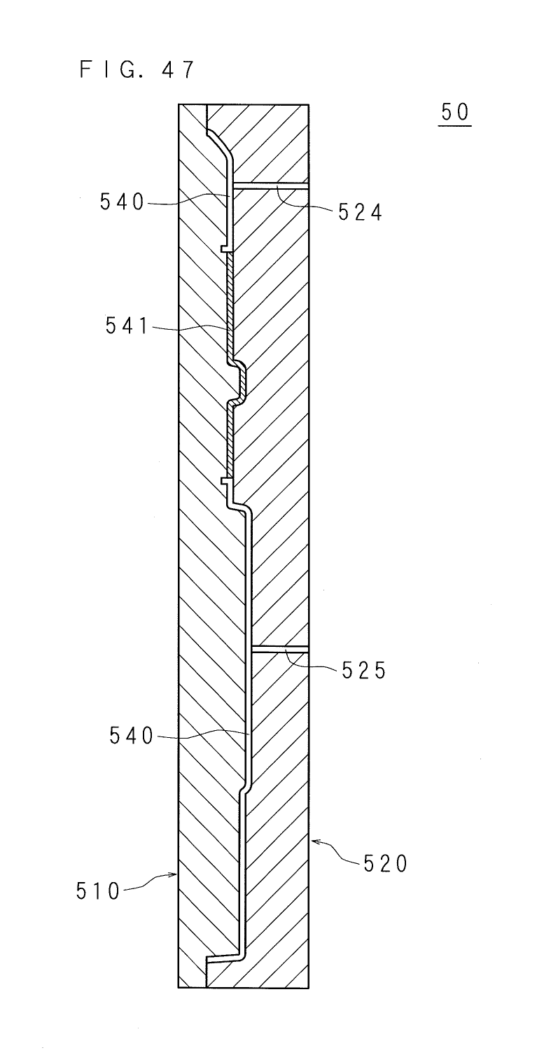

FIG. 47 is a cross-sectional view illustrating another example of a mold 50 for molding the back cabinet 4. The top and bottom direction in FIG. 47 correspond to the top and bottom side of the back cabinet 4, respectively. The right and left directions in FIG. 47 correspond to the upper side and underside of the back cabinet 4, respectively. FIG. 47 is a cross-sectional view of the mold 50 taken by cutting in a sectional plane parallel to the vertical direction and the normal line of the back cabinet 4.

The mold 50 includes a male mold 510 and a female mold 520. The male mold 510 is a movable core, and the female mold 520 is a fixed cavity. The female mold 520 has runners 524 and 525 which are flow passages for a resin material to be filled in cavity 540 portion inside the mold 50. The runners 524 and 525 are flow passages for forming the site corresponding to the back cabinet body 41. The mold 50 is closed and open by sliding the male mold 510, for example.

Cavities 540 and 541 are formed inside of the closed mold 50. The cavity 540 is a space corresponding to the back cabinet body 41, and the cavity 541 is a space corresponding to the cover 42, respectively. The site of the cavity 540 contacting with the cavity 541 is a site corresponding to the back cabinet body 41 contacting the site corresponding to the cover 42, and is protruded to the front side of the television receiving apparatus 1. A high flame retardancy resin material filled into the protruded cavity 540 forms the site having a function of the enclosure.

Next, a method of molding the back cabinet 4 according to embodiment 6-2 will be described. First, the site of the back cabinet 4 corresponding to the cover 42 is molded. For this, a mold (not illustrated) for molding the site of the back cabinet 4 corresponding to the cover 42 is prepared. A low flame retardancy resin material is injected into the prepared mold, the low flame retardancy resin material is cooled, and then the molded part relating to the site of the back cabinet 4 corresponding to the cover 42 is taken out form the mold.

A member of the back cabinet 4 corresponding to the previously formed cover 42 is mounted in the female mold 520 corresponding to the cavity 541. The mold 50 is closed by sliding the male mold 510. Then, a high flame retardancy resin material is injected into the cavity 540 corresponding to the back cabinet body 41 from the nozzle through the runners 524 and 525. After the high flame retardancy resin material forming the site corresponding to the back cabinet body 41 is cooled, the mold 50 is open, and then the molded part of the back cabinet 4 is taken out from the mold 50.

### Embodiment 6-3

Embodiment 6 is related to a configuration in which runners for injecting a high flame retardancy resin material and a low flame retardancy resin material into cavities of a mold respectively corresponding to the back cabinet body 41 and the cover 42, and the high and low flame retardancy resin materials are simultaneously injected into the mold through the respective runners.

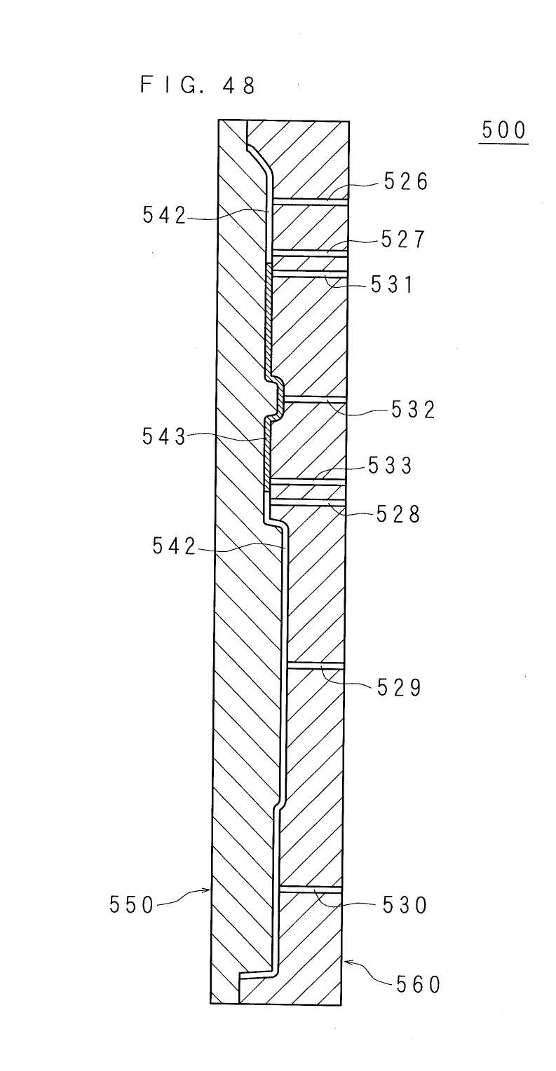

FIG. 48 is a cross-sectional view illustrating another example of a mold 500 for molding the back cabinet 4. The top and bottom direction in FIG. 48 correspond to the top and bottom side of the back cabinet 4, respectively. The right and left directions in FIG. 48 correspond to the upper side and underside of the back cabinet 4, respectively. FIG. 48 is a cross-sectional view of the mold 500 taken by cutting in a sectional plane parallel to the vertical direction and the normal line of the back cabinet 4.

The mold 500 includes a male mold 550 and a female mold 560 male. The male mold 550 is a movable core, and the female mold 560 is a fixed cavity.

Cavities 542 and 543 are formed inside of the closed mold 500. The cavity 542 is a space corresponding to the back cabinet body 41, and the cavity 543 is a space corresponding to the cover 42, respectively.

The female mold 560 has runners 526 to 533 which are flow passages of the resin material filled in the cavities 542 and 543 inside of the mold 500. Runners 526, 527, 528, 529 and 530 are flow passages for molding the site corresponding to the back cabinet body 41. The runners 531, 532, and 533 are flow passages for molding the site corresponding to the cover 42.

The mold 500 is closed and open by sliding the male mold 550, for example.

Boundaries of the cavity 542 and the cavity 543 are disposed between gates for the runner 527 and the runner 531, as well as between gates for the runner 528 and the runner 533. It is preferable that the boundary between the region corresponding to the back cabinet body 41 and the region corresponding to the cover 42 in the back cabinet 4 after forming is not significantly shifted by the flow of the resin material. For this, the gate for the runner 527 and the runner 531, as well as the gate for the runner 528 and the runner 533 are located adjacent to the boundary between the cavity 542 and the cavity 543.

Next, a method of molding the back cabinet 4 according to embodiment 6-3 will be described.

First, the mold 500 is closed by sliding the male mold 550. Then, a high flame retardancy resin material is injected into the cavity 542 of the site corresponding to the back cabinet body 41 from the nozzle through the runners 526 to 530. At the same time, a low flame retardancy resin material is injected into the cavity 543 of the site corresponding to the cover 42 from the nozzle through the runners 531 to 532. After the high and low flame retardancy resin materials are cooled, the mold 500 is open, and then the molded part of the back cabinet 4 is taken out form the mold 500.

According to the back cabinet 4 of embodiment 6-3, the region corresponding to the back cabinet body 41 and the region corresponding to the cover 42 are formed simultaneously by two-color molding in one cycle. Therefore, molding efficiency of the back cabinet 4 in embodiment 6-3 is high.

The mold 500 has no partition part such as the partition part 53 of the mold 5 in embodiment 6-1. Therefore, the low and high flame retardancy resin materials are partially mixed during the injecting or pressure maintaining process. Accordingly, the boundary between the back cabinet body 41 to be an enclosure and the cover 42 may be shifted in terms of the safety so as to meet the safety standards. That is, the position of the gate for separately injecting the low and high flame retardancy resin materials may be shifted in a direction to further decrease the area of the portion corresponding to the cover 42, or a direction to narrow the cavity 543 in FIG. 48.

In embodiment 6, the regions which are respectively corresponding to the back cabinet body 41 and the cover 42 of embodiment 1 are molded in one body by the two-color molding. However, the present invention is not limited thereto, and the regions which are respectively corresponding to the upper back cabinet 45 and the lower back cabinet 46 of embodiment 5 may also be formed in one body by the two-color molding. In this case, a method for providing the partition part in the mold may be considered. In addition, a method that, after the region corresponding to the upper back cabinet 45 or the lower back cabinet 46 is molded in advance, the molded region is mounted in the mold, and then the remaining region is molded, may also be considered. Further, a method that, by injecting the high and low flame retardancy resin materials into the mold simultaneously, the region respectively corresponding to the upper back cabinet 45 and the lower back cabinet 46 is molded simultaneously, may also be considered.

According to the manufacturing method of the back cabinet 4 of embodiment 6, the region made of the high flame retardancy resin material and the region made of the low flame retardancy resin material can be integrally molded in a short time. Therefore, according to the manufacturing method of the back cabinet 4 of embodiment 6, it is possible to reduce the manufacturing costs of the back cabinet 4.

When the region made of the high flame retardancy resin material and the region made of the low flame retardancy resin material are molded separately, each part needs to provide a structure for combining these regions. Further, in the assembling work of the television receiving apparatus 1, a process for combining these regions is required. However, when assembling the television receiving apparatus 1 by the back cabinet 4 molded by the manufacturing method according to embodiment 6, it is possible to use the back cabinet 4 in which the region made of the high flame retardancy resin material and the region made of the low flame retardancy resin material are molded in one body from the beginning. Therefore, according to the manufacturing method of the back cabinet 4 of embodiment 6, it is possible to reduce the costs and time required for assembling the television receiving apparatus 1.

Embodiment 6 is as described above, and other than that is the same as embodiments 1 to 5, such that the corresponding parts have the same reference numbers, and a detailed description, operations and effects thereof will be omitted.

As this invention may be embodied in several forms without departing from the spirit of essential characteristics thereof, the present embodiments are therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1-8. (canceled)

9. A display apparatus comprising:
a display unit having a display surface on a front side of the display unit;
a front cabinet enclosing a peripheral edge part of the display unit; and
a back cabinet covering a back side of the display unit,
wherein the back cabinet includes
a back cabinet body in which an opening part is formed and
a cover body which is attached to the back cabinet body so as to close the opening part, and
the cover body is made of a material different from the material constituting the back cabinet body.

10. The display apparatus according to claim 9, wherein the cover body is made of a material having a lower flame retardancy than the back cabinet body.

11. The display apparatus according to claim 10, wherein the cover body and the back cabinet body are respectively made of resin materials having different flame retardancy.

12. The display apparatus according to claim 11, further comprising a circuit board fixed between the display unit and the back cabinet,
wherein the opening part is provided in a region not facing the circuit board in the back cabinet body.

13. The display apparatus according to claim 12, wherein the opening part is provided in a region facing the display unit in the back cabinet body, and
the back cabinet body includes
an inner cylinder and
an outer cylinder enclosing the inner cylinder, which are formed on a front surface of a peripheral edge of the opening part.

14. The display apparatus according to claim 13, wherein the cover body includes a plurality of locking claws provided on the peripheral edge part of the front surface of the cover body to be locked to a peripheral wall end of the inner cylinder.

15. The display apparatus according to claim 14, wherein the locking claw has
a base provided on the front surface of the cover body, and
a reinforcing rib provided on a corner forming the inner surface of the base and the front surface of the cover body.

16. The display apparatus according to claim 15, wherein an opening surface of the outer cylinder, the opening part and the cover body are formed in a rectangular shape, respectively,
the cover body includes a positioning protrusion which is provided on one long side surface of the cover body to position the cover body in line with the back cabinet body,
the outer cylinder includes an aperture which is provided in one peripheral wall facing the positioning protrusion in a longitudinal of the outer cylinder to be loosely inserted the positioning protrusion,
the outer cylinder has a guide protrusion which is provided on an inner surface of the one peripheral wall of the outer cylinder around the aperture to guide the positioning protrusion into the aperture,
the guide protrusion has a concave provided on a rear surface of the guide protrusion, and
the inner cylinder is provided on the peripheral edge of the opening part including an inner periphery of the guide protrusion.

17. A television receiving apparatus comprising:
the display apparatus according to claim 1; and
a receiving unit which receives television broadcasts,
wherein the display apparatus displays an image of the television broadcasts received by the receiving unit.
